(19) United States
(12) Patent Application Publication
(10) Pub. No.: US 2026/0079369 A1
(43) Pub. Date: Mar. 19, 2026

(54) ACTIVE MATRIX SUBSTRATE, LIQUID CRYSTAL DISPLAY DEVICE INCLUDING THE SAME, AND METHOD OF MANUFACTURING ACTIVE MATRIX SUBSTRATE

(71) Applicant: SHARP KABUSHIKI KAISHA, Sakai City (JP)

(72) Inventor: KATSUNORI MISAKI, Sakai city (JP)

(21) Appl. No.: 19/299,805

(22) Filed: Aug. 14, 2025

(30) Foreign Application Priority Data
Sep. 17, 2024 (JP) 2024-160012

(51) Int. Cl. G02F 1/1362; G02F 1/1368; H10D 86/01; H10D 86/60

(52) U.S. Cl. CPC G02F 1/136222; G02F 1/136209; G02F 1/1368; H10D 86/0221; H10D 86/60

(57) ABSTRACT

A base substrate; a plurality of TFTs provided on the base substrate, the plurality of TFTs corresponding to a plurality of subpixels; a color filter provided on the plurality of TFTs, the color filter being disposed with colored layers of predetermined colors corresponding to the plurality of subpixels; a plurality of pixel electrodes provided on an upper side of the color filter, the plurality of pixel electrodes corresponding to the plurality of subpixels; a capacitance insulating film provided on the plurality of pixel electrodes; a common electrode provided commonly to the plurality of subpixels on the capacitance insulating film; and an anti-reflection layer having belt shapes, each belt shape of the anti-reflection layer overlapping a boundary portion between the colored layers having different colors from each other in the color filter, the anti-reflection layer being formed by layering a first metal layer, the capacitance insulating film, and a second metal layer in order are provided, and the common electrode covers the second metal layer.

### CROSS-REFERENCE TO RELATED APPLICATIONS

This application claims the benefit of priority to Japanese Patent Application Number 2024-160012 filed on Sep. 17, 2024. The entire contents of the above-identified application are hereby incorporated by reference.

### BACKGROUND

### Technical Field

The disclosure relates to an active matrix substrate, a liquid crystal display device including the active matrix substrate, and a method of manufacturing the active matrix substrate.

In recent years, liquid crystal display devices often use a color filter-on-array (hereinafter also referred to as COA) structure in which a color filter is provided on an active matrix substrate (array substrate) and alignment with a counter substrate is not required.

For example, JP 2017-116821 A discloses a liquid crystal display device in which pixel electrodes and a common electrode are provided on a substrate having a COA structure and that uses a Fringe Field Switching (FFS) mode, which is one in-plane switching mode.

### SUMMARY

In a liquid crystal display device including an active matrix substrate having a COA structure in which pixel electrodes, a capacitance insulating film made of an inorganic insulating film, and a common electrode formed with a slit or the like for liquid crystal alignment are provided in order, an anti-reflection layer including a metal layer disposed between colored layers in a color filter may be formed on the common electrode. Note that an inorganic protection film is interposed between the pixel electrode and the common electrode to form an auxiliary capacity. In this case, when the anti-reflection layer is formed by dry etching, the capacitance insulating film exposed from the common electrode is etched. Thus, steps may be formed at edges of the capacitance insulating film. When this happens, light leakage due to alignment disorder of the liquid crystal layer is likely to occur due to the steps, thereby degrading optical characteristics of the liquid crystal display device.

The disclosure has been made in view of such circumstances, and an object thereof is to suppress formation of steps of a capacitance insulating film that are caused by formation of an anti-reflection layer.

In order to achieve the above object, according to the disclosure, there is provided an active matrix substrate including a base substrate, a plurality of thin film transistors provided on the base substrate, the plurality of thin film transistors corresponding to a plurality of subpixels, a color filter provided on the plurality of thin film transistors, the color filter being disposed with colored layers of predetermined colors corresponding to the plurality of subpixels, a plurality of pixel electrodes provided on an upper side of the color filter, the plurality of pixel electrodes corresponding to the plurality of subpixels, a capacitance insulating film provided on the plurality of pixel electrodes, a common electrode provided commonly to the plurality of subpixels on the capacitance insulating film, and an anti-reflection layer having belt shapes, each belt shape of the anti-reflection layer overlapping a boundary portion between the colored layers having different colors from each other in the color filter, the anti-reflection layer being formed by layering a first metal layer, the capacitance insulating film, and a second metal layer in order, wherein the common electrode covers the second metal layer.

Further, according to the disclosure, there is provided a liquid crystal display device including the above-described active matrix substrate, a counter substrate facing the active matrix substrate, and a liquid crystal layer provided between the active matrix substrate and the counter substrate.

Further, according to the disclosure, there is provided a method of manufacturing an active matrix substrate including forming a plurality of thin film transistors corresponding to a plurality of subpixels on a base substrate as thin film transistor formation, forming a color filter disposed with colored layers of predetermined colors corresponding to the plurality of subpixels on the plurality of thin film transistors as color filter formation, forming a plurality of pixel electrodes corresponding to the plurality of subpixels on an upper side of the color filter as pixel electrode formation, forming a first metal layer having belt shapes, each belt shape of the first metal layer overlapping a boundary portion between the colored layers having different colors from each other in the color filter as first formation for anti-reflection layer, forming a capacitance insulating film on the plurality of pixel electrodes as capacitance insulating film formation, forming a second metal layer having belt shapes, each belt shape of the second metal layer overlapping the boundary portion between the colored layers as second formation for anti-reflection layer, and forming a common electrode covering the second metal layer as common electrode formation.

According to the disclosure, formation of steps of the capacitance insulating film that are caused by the formation of the anti-reflection layer can be suppressed.

### BRIEF DESCRIPTION OF DRAWINGS

The disclosure will be described with reference to the accompanying drawings, wherein like numbers reference like elements.

FIG. 1 is a plan view of an active matrix substrate that is a component of a liquid crystal display device according to a first embodiment of the disclosure.

FIG. 2 is a cross-sectional view of the active matrix substrate and the liquid crystal display device including the active matrix substrate. The cross-sectional view is taken along a line II-II in FIG. 1.

FIG. 3 is a cross-sectional view of the active matrix substrate and the liquid crystal display device including the active matrix substrate. The cross-sectional view is taken along a line III-III in FIG. 1.

FIG. 4 is a cross-sectional view of the active matrix substrate and the liquid crystal display device including the active matrix substrate. The cross-sectional view is taken along a line IV-IV in FIG. 1.

FIG. 5 is a first cross-sectional view illustrating a state after a part of a manufacturing process of the active matrix substrate that is a component of the liquid crystal display device according to the first embodiment of the disclosure.

FIG. 6 is a second cross-sectional view subsequent to FIG. 5, illustrating a state after a part of the manufacturing process of the active matrix substrate that is a component of the liquid crystal display device according to the first embodiment of the disclosure.

FIG. 7 is a third cross-sectional view subsequent to FIG. 6, illustrating a state after a part of the manufacturing process of the active matrix substrate that is a component of the liquid crystal display device according to the first embodiment of the disclosure.

FIG. 8 is a fourth cross-sectional view subsequent to FIG. 7, illustrating a state after a part of the manufacturing process of the active matrix substrate that is a component of the liquid crystal display device according to the first embodiment of the disclosure.

FIG. 9 is a fifth cross-sectional view subsequent to FIG. 8, illustrating a state after a part of the manufacturing process of the active matrix substrate that is a component of the liquid crystal display device according to the first embodiment of the disclosure.

FIG. 10 is a sixth cross-sectional view subsequent to FIG. 9, illustrating a state after a part of the manufacturing process of the active matrix substrate that is a component of the liquid crystal display device according to the first embodiment of the disclosure.

FIG. 11 is a seventh cross-sectional view subsequent to FIG. 10, illustrating a state after a part of the manufacturing process of the active matrix substrate that is a component of the liquid crystal display device according to the first embodiment of the disclosure.

FIG. 12 is an eighth cross-sectional view subsequent to FIG. 11, illustrating a state after a part of the manufacturing process of the active matrix substrate that is a component of the liquid crystal display device according to the first embodiment of the disclosure.

FIG. 13 is a ninth cross-sectional view subsequent to FIG. 12, illustrating a state after a part of the manufacturing process of the active matrix substrate that is a component of the liquid crystal display device according to the first embodiment of the disclosure.

FIG. 14 is a tenth cross-sectional view subsequent to FIG. 13, illustrating a state after a part of the manufacturing process of the active matrix substrate that is a component of the liquid crystal display device according to the first embodiment of the disclosure.

FIG. 15 is an eleventh cross-sectional view subsequent to FIG. 14, illustrating a state after a part of the manufacturing process of the active matrix substrate that is a component of the liquid crystal display device according to the first embodiment of the disclosure.

FIG. 16 is a twelfth cross-sectional view subsequent to FIG. 15, illustrating a state after a part of the manufacturing process of the active matrix substrate that is a component of the liquid crystal display device according to the first embodiment of the disclosure.

FIG. 17 is a thirteenth cross-sectional view subsequent to FIG. 16, illustrating a state after a part of the manufacturing process of the active matrix substrate that is a component of the liquid crystal display device according to the first embodiment of the disclosure.

FIG. 18 is a fourteenth cross-sectional view subsequent to FIG. 17, illustrating a state after a part of the manufacturing process of the active matrix substrate that is a component of the liquid crystal display device according to the first embodiment of the disclosure.

FIG. 19 is a fifteenth cross-sectional view subsequent to FIG. 18, illustrating a state after a part of the manufacturing process of the active matrix substrate that is a component of the liquid crystal display device according to the first embodiment of the disclosure.

FIG. 20 is a sixteenth cross-sectional view subsequent to FIG. 19, illustrating a state after a part of the manufacturing process of the active matrix substrate that is a component of the liquid crystal display device according to the first embodiment of the disclosure.

FIG. 21 is a seventeenth cross-sectional view subsequent to FIG. 20, illustrating a state after a part of the manufacturing process of the active matrix substrate that is a component of the liquid crystal display device according to the first embodiment of the disclosure.

FIG. 22 is an eighteenth cross-sectional view subsequent to FIG. 21, illustrating a state after a part of the manufacturing process of the active matrix substrate that is a component of the liquid crystal display device according to the first embodiment of the disclosure.

FIG. 23 is a nineteenth cross-sectional view subsequent to FIG. 22, illustrating a state after a part of the manufacturing process of the active matrix substrate that is a component of the liquid crystal display device according to the first embodiment of the disclosure.

FIG. 24 is a first cross-sectional view illustrating a state after a part of a modified example of the manufacturing process of the active matrix substrate that is a component of the liquid crystal display device according to the first embodiment of the disclosure.

FIG. 25 is a second cross-sectional view subsequent to FIG. 24, illustrating a state after a part of the modified example of the manufacturing process of the active matrix substrate that is a component of the liquid crystal display device according to the first embodiment of the disclosure.

FIG. 26 is a third cross-sectional view subsequent to FIG. 25, illustrating a state after a part of the modified example of the manufacturing process of the active matrix substrate that is a component of the liquid crystal display device according to the first embodiment of the disclosure.

FIG. 27 is a fourth cross-sectional view subsequent to FIG. 26, illustrating a state after a part of the modified example of the manufacturing process of the active matrix substrate that is a component of the liquid crystal display device according to the first embodiment of the disclosure.

FIG. 28 is a plan view of an active matrix substrate that is a component of a liquid crystal display device according to a second embodiment of the disclosure.

FIG. 29 is a cross-sectional view of the active matrix substrate taken along a line XXIX-XXIX in FIG. 28.

FIG. 30 is a cross-sectional view of the active matrix substrate taken along a line XXX-XXX in FIG. 28.

FIG. 31 is a plan view of an active matrix substrate that is a component of a liquid crystal display device according to a third embodiment of the disclosure.

FIG. 32 is a plan view of an active matrix substrate that is a component of a liquid crystal display device according to a fourth embodiment of the disclosure.

FIG. 33 is a plan view of an active matrix substrate that is a component of a liquid crystal display device according to a fifth embodiment of the disclosure.

FIG. 34 is a cross-sectional view of the active matrix substrate taken along a line XXXIV-XXXIV in FIG. 33.

FIG. 35 is a cross-sectional view of the active matrix substrate taken along a line XXXV-XXXV in FIG. 33.

FIG. 36 is a cross-sectional view of the active matrix substrate taken along a line XXXVI-XXXVI in FIG. 33.

### DESCRIPTION OF EMBODIMENTS

Embodiments according to the disclosure will be described below in detail with reference to the drawings. Note that the disclosure is not limited to the embodiments to be described below.

### First Embodiment

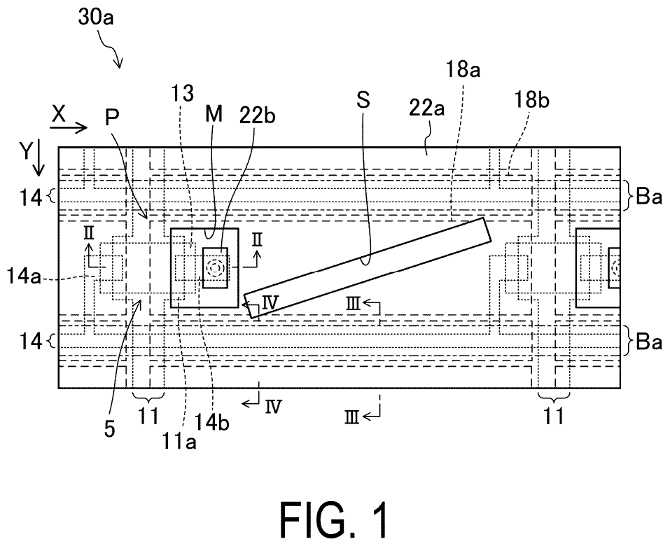

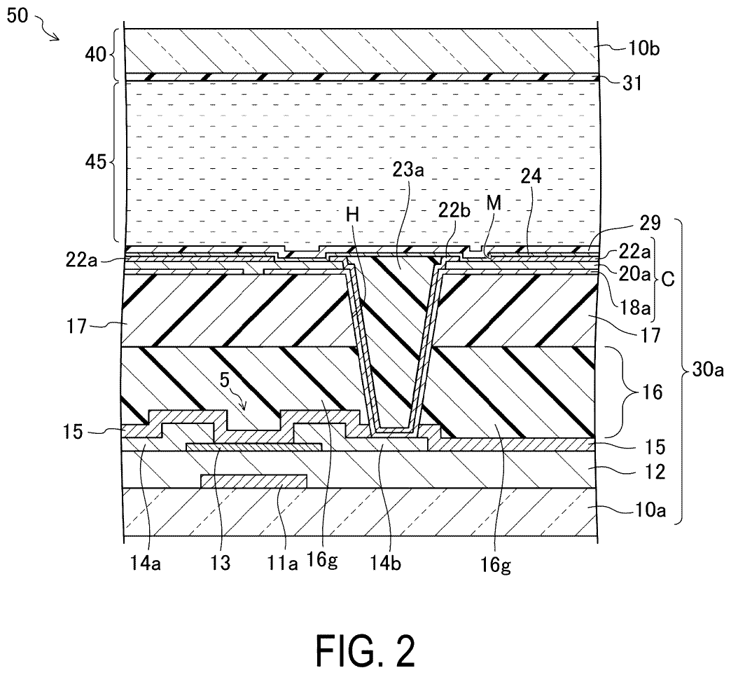

FIGS. 1 to 27 illustrate a first embodiment of an active matrix substrate, a liquid crystal display device including the active matrix substrate, and a method of manufacturing the active matrix substrate, according to the disclosure. Here, FIG. 1 is a plan view of an active matrix substrate 30a that is a component of a liquid crystal display device 50 according to the present embodiment. Further, FIGS. 2, 3, and 4 are cross-sectional views of the liquid crystal display device 50 taken along lines II-II, III-III, and IV-IV, respectively, in FIG. 1.

As illustrated in FIGS. 2 to 4, the liquid crystal display device 50 includes the active matrix substrate 30a having a COA structure, a counter substrate 40 provided to face the active matrix substrate 30a, and a liquid crystal layer 45 provided between the active matrix substrate 30a and the counter substrate 40. In the liquid crystal display device 50, a plurality of subpixels P (see FIG. 1) are provided in a matrix shape in a display region that displays an image. In the display region, as illustrated in FIGS. 2 to 4, subpixels P for gray scale display of red with red layers 16r, subpixels P for gray scale display of green with green layers 16g, and subpixels P for gray scale display of blue with blue layers (not illustrated) are provided so as to be adjacent to one another. Note that in the display region, one pixel is constituted by three adjacent subpixels P for gray scale display of red, green, and blue.

As illustrated in FIGS. 2 to 4, the active matrix substrate 30a includes a base substrate 10a such as a glass substrate, a plurality of Thin Film Transistors (hereinafter also referred to as TFTs) 5 provided on the base substrate 10a and corresponding to the plurality of subpixels P, a color filter 16 provided on the plurality of TFTs 5, an organic protection film 17 provided on the color filter 16, a plurality of pixel electrodes 18a provided in a matrix shape on the organic protection film 17 and corresponding to the plurality of subpixels P, a capacitance insulating film 20a provided on the plurality of pixel electrodes 18a, a common electrode 22a provided commonly to the plurality of subpixels P on the capacitance insulating film 20a, an inorganic protection film 24 provided on the common electrode 22a, and an alignment film 29 provided on the inorganic protection film 24. As illustrated in FIG. 1, the active matrix substrate 30a includes, on the base substrate 10a in the display region, a plurality of gate lines 11 extending parallel to each other in the Y direction in the drawing, and a plurality of source lines 14 extending parallel to each other in the X direction in the drawing so as to intersect the gate lines 11 with a gate insulating film 12 (see FIGS. 2 to 4) interposed therebetween.

As illustrated in FIG. 2, the TFT 5 includes a gate electrode 11a provided on the base substrate 10a, the gate insulating film 12 provided to cover the gate electrode 11a, a semiconductor layer 13 provided in an island shape on the gate insulating film 12 so as to overlap the gate electrode 11a, and a source electrode 14a and a drain electrode 14b provided on the semiconductor layer 13 so as to be separated from each other. The TFT 5 is provided for each of intersections of the gate lines 11 and the source lines 14, that is, for each subpixel P. The gate electrode 11a is a wide portion of the gate line 11, as illustrated in FIG. 1. The semiconductor layer 13 includes, for example, an intrinsic amorphous silicon layer provided on the gate insulating film 12 side, and a pair of n⁺ amorphous silicon layers provided on the intrinsic amorphous silicon layer and disposed such that a channel region of the intrinsic amorphous silicon layer is exposed and separated from each other. As illustrated in FIG. 1, the source electrode 14a is an L-shaped protrusion on a side of the source line 14 and is provided so as to be in contact with one of the pair of n⁺ amorphous silicon layers of the semiconductor layer 13. The drain electrode 14b is provided so as to be in contact with the other of the pair of n⁺ amorphous silicon layers of the semiconductor layer 13 and is electrically connected to the pixel electrode 18a via a contact hole H formed in the color filter 16 and the organic protection film 17, as illustrated in FIG. 2. Note that although the semiconductor layer 13 including the intrinsic amorphous silicon layer is exemplified in the present embodiment, the semiconductor layer 13 may be constituted by, for example, a polysilicon film made of Low Temperature PolySilicon (LTPS), an In—Ga—Zn—O based oxide semiconductor film, or the like.

The color filter 16 is provided such that colored layers of predetermined colors are disposed corresponding to the subpixels P, and specifically, the color filter 16 includes the red layer 16r provided as a colored layer corresponding to the subpixel P for gray scale display of red, the green layer 16g provided as a colored layer corresponding to the subpixel P for gray scale display of green, and the blue layer (not illustrated) provided as a colored layer corresponding to the subpixel P for gray scale display of blue, as illustrated in FIGS. 2 to 4. Note that an interlayer insulating film 15 is provided between the TFT 5 and the color filter 16. Here, each of the gate insulating film 12, the interlayer insulating film 15, the capacitance insulating film 20a, and the inorganic protection film 24 is constituted by a single-layer film or a layered film of inorganic insulating films made of, for example, silicon nitride, silicon oxide, or silicon oxynitride.

The organic protection film 17 is made of, for example, a transparent organic resin material such as an acrylic resin.

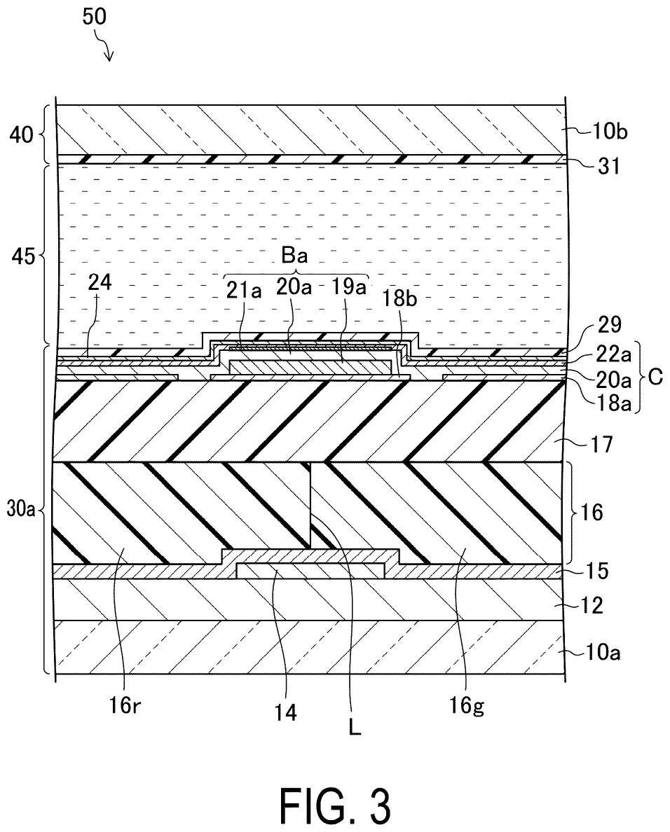

As illustrated in FIGS. 1 to 4, the pixel electrode 18a is provided in a rectangular shape on the organic protection film 17. Here, as illustrated in FIGS. 2 and 3, the pixel electrode 18a constitutes an auxiliary capacity C of each subpixel P together with the common electrode 22a and the capacitance insulating film 20a provided between the pixel electrode 18a and the common electrode 22a. Additionally, as illustrated in FIGS. 1, 3, and 4, a transparent conductive layer 18b made of the same material and in the same layer as those of the pixel electrodes 18a is provided in a belt shape between a pair of pixel electrodes 18a adjacent to each other in the Y direction in FIG. 1 so as to overlap the source line 14 and a boundary portion L between colored layers (for example, the red layer 16r and the green layer 16g) of different colors from each other in the color filter 16. Note that as illustrated in FIGS. 1, 3, and 4, an anti-reflection layer Ba is provided on the transparent conductive layer 18b.

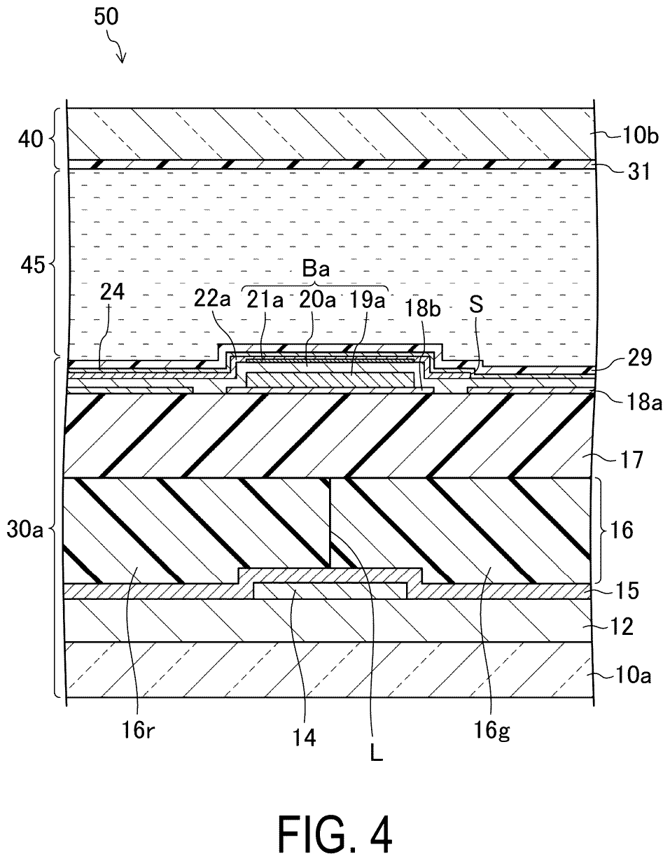

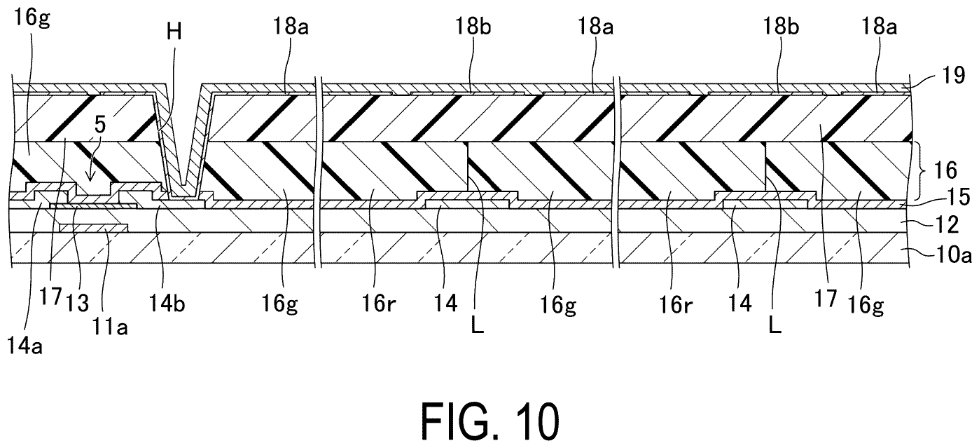

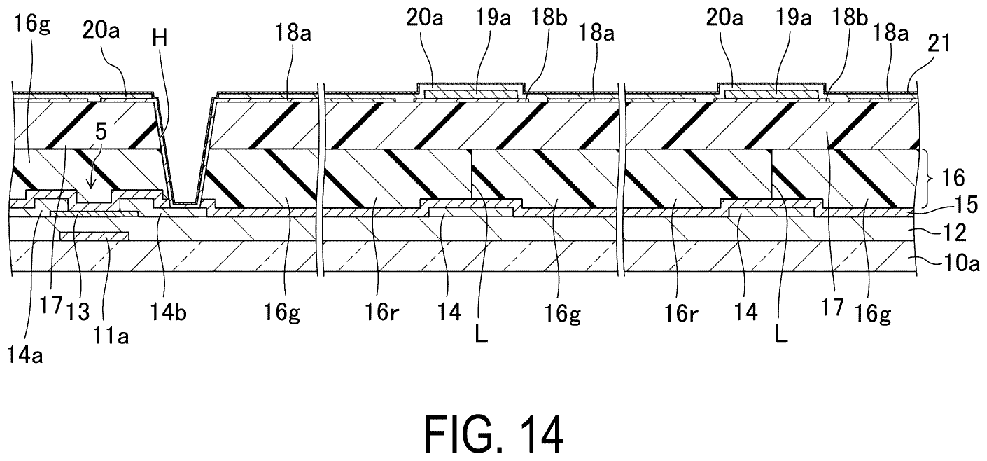

As illustrated in FIGS. 1, 3, and 4, the anti-reflection layer Ba is provided in belt shapes over the entire display region such that each belt shape overlaps the source line 14 and the boundary portion L between the colored layers (for example, the red layer 16r and the green layer 16g) of different colors from each other in the color filter 16, same as the transparent conductive layer 18b. Further, as illustrated in FIGS. 3 and 4, the anti-reflection layer Ba includes a first metal layer 19a, the capacitance insulating film 20a, and a second metal layer 21a layered in order on the transparent conductive layer 18b, and is configured to suppress reflection of light incident from the liquid crystal layer 45 side by reflecting the light incident from the liquid crystal layer 45 side at the second metal layer 21a, reflecting, at the first metal layer 19a, light transmitted through the second metal layer 21a without being reflected at the second metal layer 21a, and causing the light reflected at the second metal layer 21a and the light reflected at the first metal layer 19a to cancel each other. Here, the first metal layer 19a is constituted by, for example, a first metal film 19 (see FIG. 10) such as a tungsten film, a molybdenum film, or a molybdenum-tungsten alloy film with a thickness of approximately 60 nm or larger. Further, the capacitance insulating film 20a is constituted by, for example, an inorganic insulating film such as a silicon nitride film with a refractive index of approximately from 1.8 to 2.1 and a thickness of approximately from 40 nm to 100 nm. Further, the second metal layer 21a is constituted by, for example, a second metal film 21 (see FIG. 14 and the like) such as a tungsten film or a molybdenum film with a thickness of approximately from 3 nm to 8 nm.

As illustrated in FIGS. 3 and 4, the common electrode 22a is provided so as to cover the second metal layer 21a of the anti-reflection layer Ba. Further, as illustrated in FIGS. 1 and 4, a slit S for aligning the liquid crystal layer 45 is provided for each subpixel P in a belt shape in the common electrode 22a so as to extend through the common electrode 22a. Further, as illustrated in FIGS. 1 and 2, the common electrode 22a is provided with an opening M having a rectangular shape. The opening M overlaps the contact hole H and extends through the common electrode 22a. Furthermore, as illustrated in FIGS. 1 and 2, inside the opening M of the common electrode 22a, a transparent conductive layer 22b formed in the same layer with the same material as those of the common electrode 22a is provided in a recessed shape so as to be separated from the common electrode 22a and to overlap a bottom surface and a side surface of the contact hole H. Note that as illustrated in FIG. 2, a resin layer 23a is provided between the transparent conductive layer 22b and the inorganic protection film 24.

The alignment film 29 and an alignment film 31, which will be described below, are made of, for example, a polyimide resin whose surface is subjected to rubbing.

As illustrated in FIGS. 2 to 4, the counter substrate 40 includes a base substrate 10b such as a glass substrate, and the alignment film 31 provided on the base substrate 10b.

The liquid crystal layer 45 is made of, for example, a nematic liquid crystal material having electro-optical properties. The liquid crystal layer 45 is sealed between the active matrix substrate 30a and the counter substrate 40 by using a sealing member having a frame-like shape that bonds the active matrix substrate 30a and the counter substrate 40 to each other in a frame region around the display region.

In the liquid crystal display device 50 having the above-described configuration, a predetermined voltage is applied to the auxiliary capacity C and the liquid crystal layer 45 disposed between each pixel electrode 18a and the common electrode 22a, and the alignment state of the liquid crystal layer 45 is changed by an electrical field generated in a direction along the surface of the substrate, that is, in a horizontal direction, thereby adjusting the transmittance of light passing through the panel of each subpixel P to display an image.

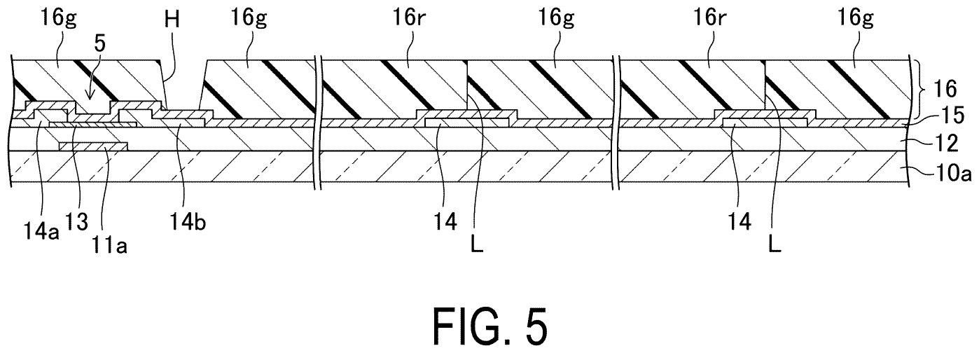

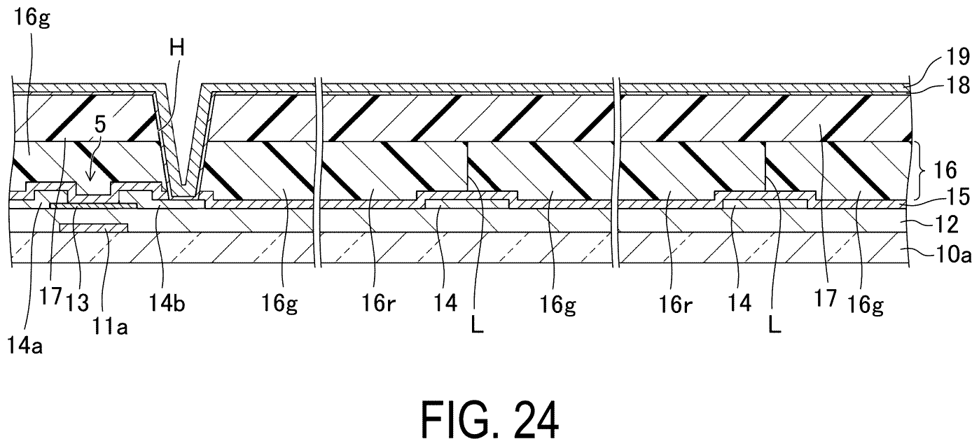

Next, a method of manufacturing the liquid crystal display device 50 according to the present embodiment will be described, focusing on a method of manufacturing the active matrix substrate 30a. Here, FIGS. 5 to 23 are respectively first to nineteenth cross-sectional views sequentially illustrating a part of a manufacturing process of the active matrix substrate 30a. Further, FIGS. 24 to 27 are respectively first to fourth cross-sectional views illustrating a part of a modified example of the manufacturing process of the active matrix substrate 30a. Note that in each of the cross-sectional views of FIGS. 5 to 27, a right side portion, a center portion, and a left side portion in the drawing across a break line indicate portions corresponding to the cross-sectional views of FIGS. 2, 3, and 4, respectively. Further, the manufacturing process of the active matrix substrate 30a includes, in order, TFT formation, color filter formation, pixel electrode formation, first formation for anti-reflection layer, capacitance insulating film formation, second formation for anti-reflection layer, and common electrode formation.

First, an aluminum film (with a thickness of approximately 300 nm) and a molybdenum niobium film (with a thickness of approximately 50 nm) are formed in order on the base substrate 10a such as a glass substrate by, for example, sputtering to form a metal layered film, and then the metal layered film is subjected to photolithography, etching, and resist stripping and cleaning, thereby forming the gate lines 11 including the gate electrodes 11a.

Subsequently, an inorganic insulating film (with a thickness of approximately 350 nm) such as a silicon nitride film or a silicon oxide film, an intrinsic amorphous silicon film (with a thickness of approximately 120 nm), and a phosphorus-doped n⁺ amorphous silicon film (with a thickness of approximately 30 nm) are formed in order by, for example, plasma Chemical Vapor Deposition (CVD) on the surface of the substrate on which the gate lines 11 are formed, and then the layered film of the intrinsic amorphous silicon film and the n⁺ amorphous silicon film is subjected to photolithography, etching, and resist stripping and cleaning, thereby forming the gate insulating film 12 and a semiconductor forming layer.

Thereafter, a titanium film (with a thickness of approximately 30 nm), an aluminum film (with a thickness of approximately 300 nm), and a titanium film (with a thickness of approximately 50 nm) are formed in order by, for example, sputtering on the surface of the substrate on which the gate insulating film 12 and the semiconductor forming layer are formed to form a metal layered film, and then the metal layered film is subjected to photolithography, etching, and resist stripping and cleaning, thereby forming the source lines 14 including the source electrodes 14a and the drain electrodes 14b.

Further, the n⁺ amorphous silicon film of the semiconductor forming layer is removed by etching using the source electrodes 14a and the drain electrodes 14b as masks, thereby forming the semiconductor layer 13 and the TFTs 5 provided with the semiconductor layer 13 (TFT formation).

Subsequently, an inorganic insulating film (with a thickness of approximately 750 nm) such as a silicon nitride film or a silicon oxide film is formed by, for example, plasma CVD on the surface of the substrate on which the TFTs 5 are formed to form the interlayer insulating film 15, and then a red, green, or blue colored acrylic photosensitive resin (with a thickness of approximately 1.6 μm) is applied by, for example, spin coating or slit coating, and the applied photosensitive resin is partially exposed, and then patterned by development, thereby forming a colored layer having a selected color (for example, the red layer 16r). Further, the same or a similar step is repeated for the other two colors to form the colored layers of the other two colors (for example, the green layer 16g and the blue layer), thereby forming the color filter 16 including the contact hole H as illustrated in FIG. 5 (color filter formation).

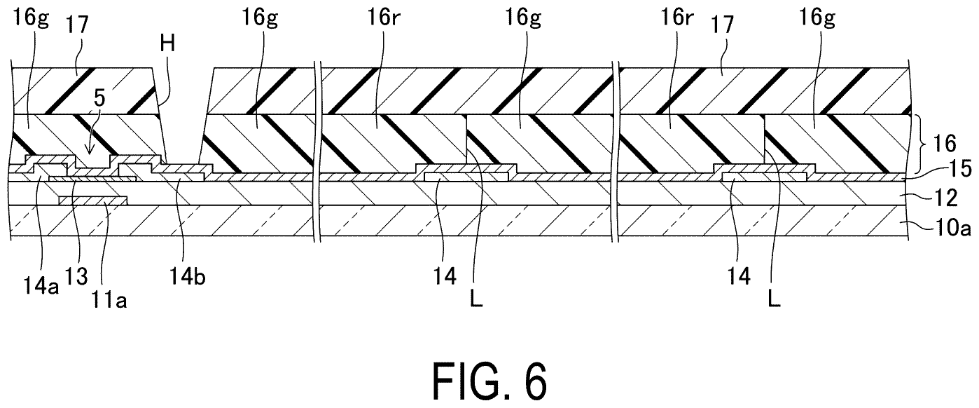

Thereafter, an acrylic photosensitive resin (with a thickness of approximately 2.0 μm) is applied by, for example, spin coating or slit coating to the surface of the substrate on which the color filter 16 is formed, and the applied photosensitive resin is partially exposed and then patterned by development, thereby forming the organic protection film 17 including the contact hole H as illustrated in FIG. 6.

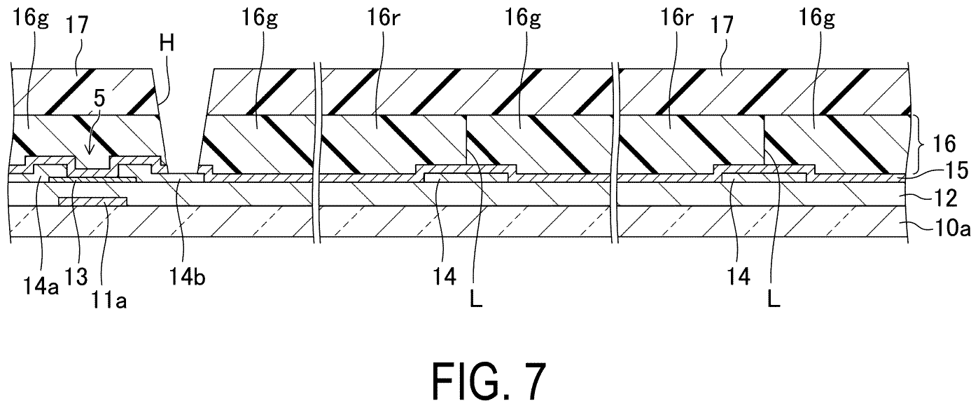

Furthermore, the interlayer insulating film 15 exposed from the contact hole H is etched to form the contact hole H in the interlayer insulating film 15 as illustrated in FIG. 7, thereby exposing a part of the drain electrode 14b from the contact hole H.

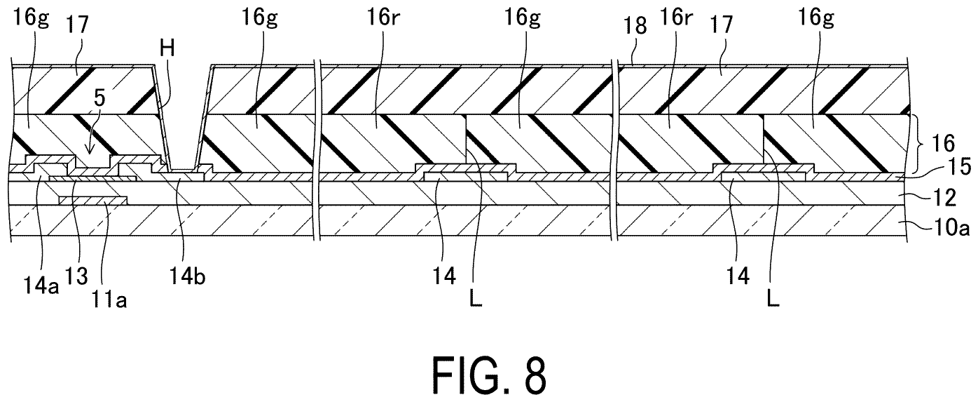

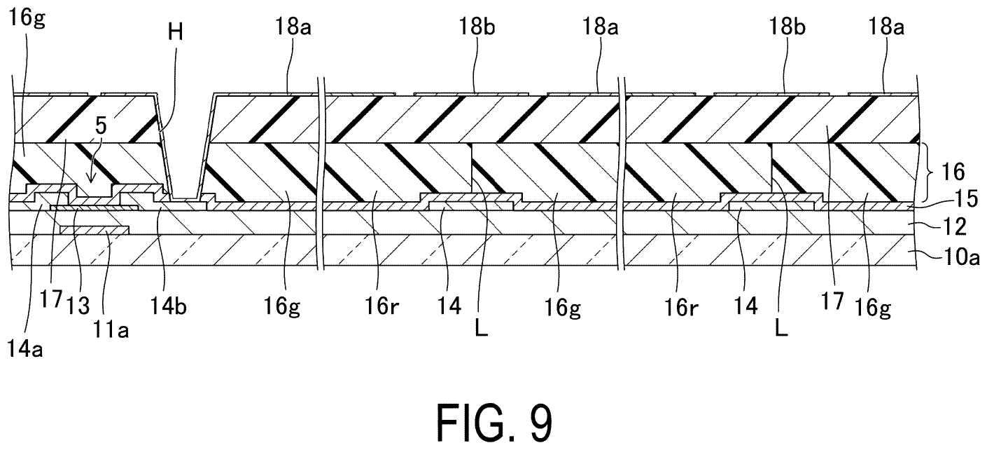

Subsequently, as illustrated in FIG. 8, a transparent conductive film 18 such as an ITO film or an IZO film with a thickness of approximately 70 nm is formed by, for example, sputtering, on the surface of the substrate on which the contact hole H is formed in the interlayer insulating film 15, and then the transparent conductive film 18 is subjected to photolithography, etching, and resist stripping and cleaning, thereby forming the pixel electrode 18a and the transparent conductive layer 18b as illustrated in FIG. 9 (pixel electrode formation). Note that when the transparent conductive film 18 is an ITO film, for example, the transparent conductive film 18 may be etched with oxalic acid, and then, after the resist is stripped and cleaned, the ITO film may be crystallized by annealing at 220° C. for 50 minutes.

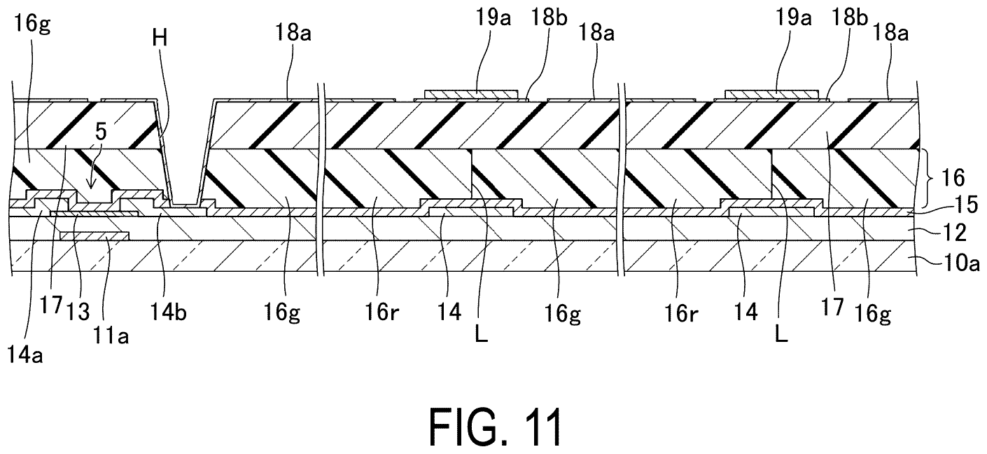

Subsequently, as illustrated in FIG. 10, the first metal film 19 such as a molybdenum film with a thickness of approximately 60 nm is formed by, for example, sputtering on the surface of the substrate on which the pixel electrode 18a is formed, and then the first metal film 19 is subjected to photolithography, etching, and resist stripping and cleaning, thereby forming the first metal layer 19a as illustrated in FIG. 11 (first formation for anti-reflection layer). Note that for example, a mixed acid solution containing phosphoric acid, nitric acid, and acetic acid is used for etching the first metal film 19.

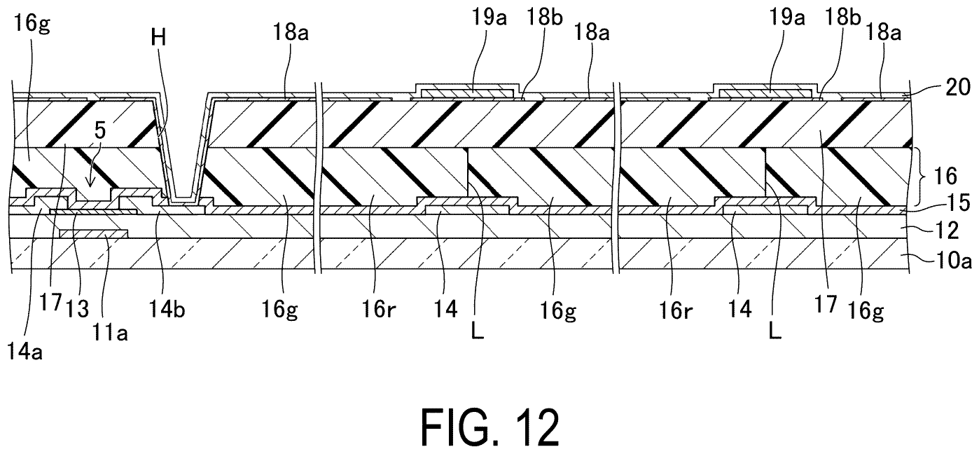

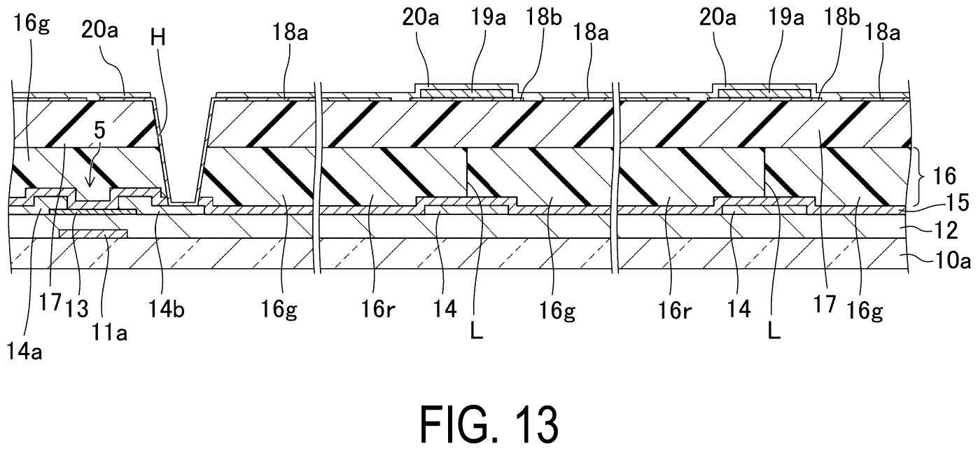

Furthermore, as illustrated in FIG. 12, an inorganic insulating film 20 such as a silicon nitride film with a thickness of approximately 40 nm to 100 nm is formed by, for example, plasma CVD on the surface of the substrate on which the first metal layer 19a is formed, and then the inorganic insulating film 20 is subjected to photolithography, etching, and resist stripping and cleaning, thereby forming the capacitance insulating film 20a as illustrated in FIG. 13 (capacitance insulating film formation). Note that the inorganic insulating film 20 is etched by dry etching using a fluorine gas, for example.

Subsequently, as illustrated in FIG. 14, the second metal film 21 such as a molybdenum film having a thickness of about 3 nm to 8 nm is formed by for example, sputtering on the surface of the substrate on which the capacitance insulating film 20a is formed.

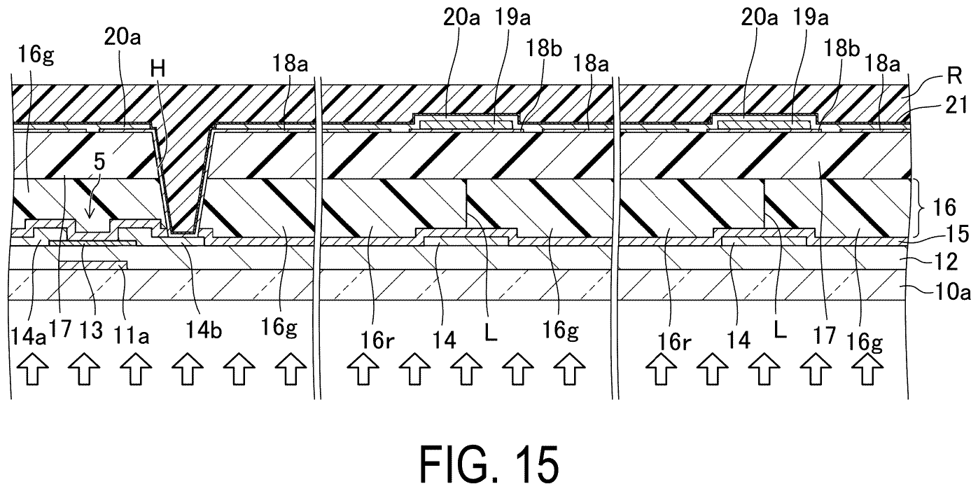

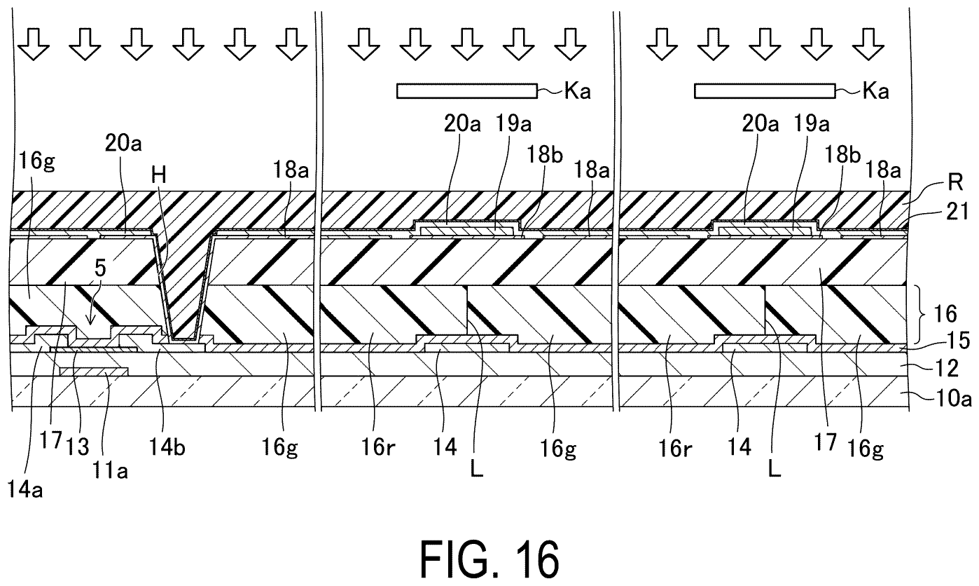

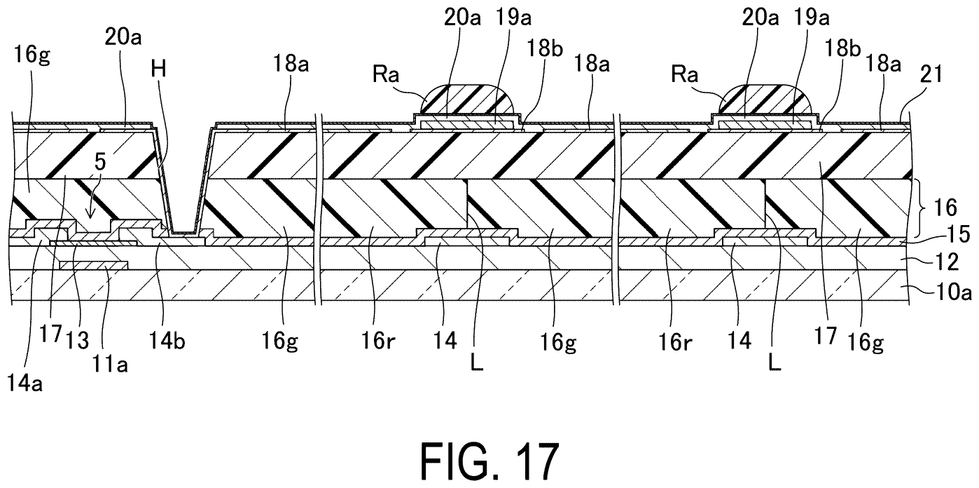

Thereafter, as illustrated in FIG. 15, a resist film R being a positive type is applied by spin coating or slit coating to the surface of the substrate on which the second metal film 21 is formed. Then, the resist film R is exposed from the base substrate 10a side (from a back surface side) through a light-shielding metal layer such as the first metal layer 19a, and the resist film R is exposed from a side opposite to the base substrate 10a (from a front surface side) through a photomask Ka as illustrated in FIG. 16, thereby forming a resist pattern Ra as illustrated in FIG. 17.

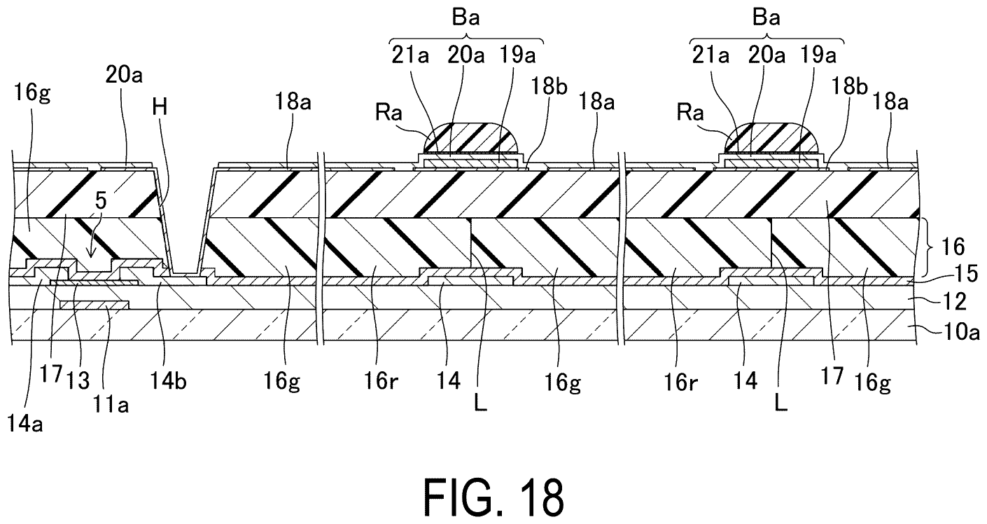

Moreover, the second metal film 21 exposed from the resist pattern Ra is etched and patterned to form the second metal layer 21a as illustrated in FIG. 18 (second formation for anti-reflection layer).

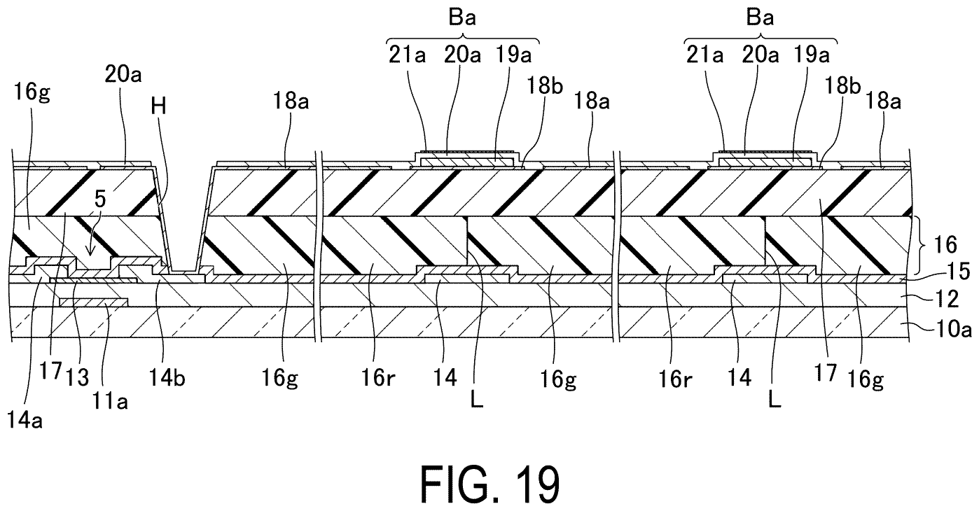

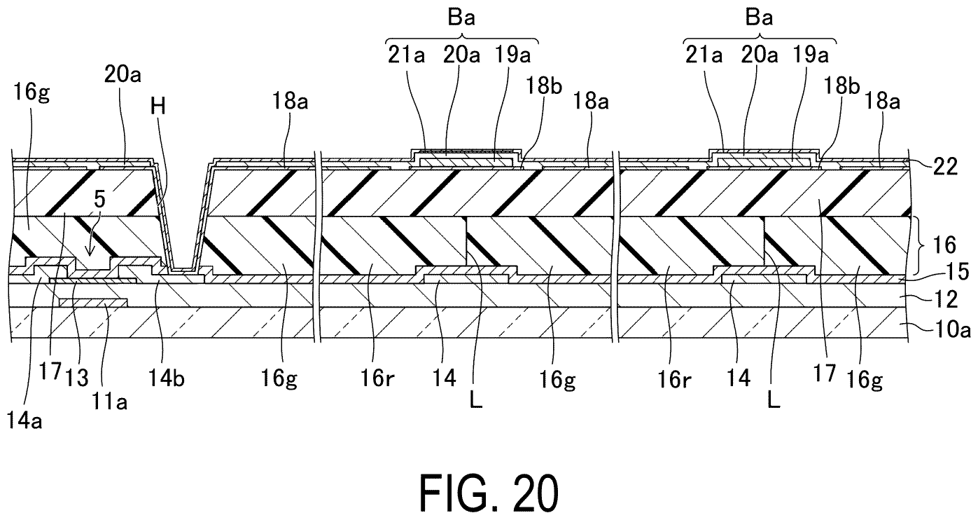

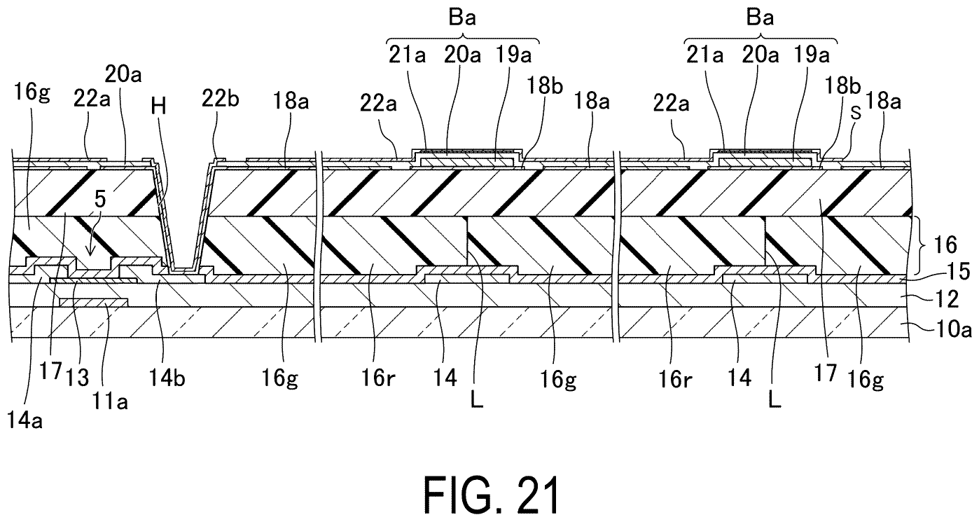

Subsequently, after the resist pattern Ra is stripped and cleaned as illustrated in FIG. 19, a transparent conductive film 22 such as an ITO film or an IZO film with a thickness of approximately 70 nm is formed by, for example, sputtering as illustrated in FIG. 20, and then the transparent conductive film 22 is subjected to photolithography, etching, and resist stripping and cleaning, thereby forming the common electrode 22a and the transparent conductive layer 22b as illustrated in FIG. 21 (common electrode formation).

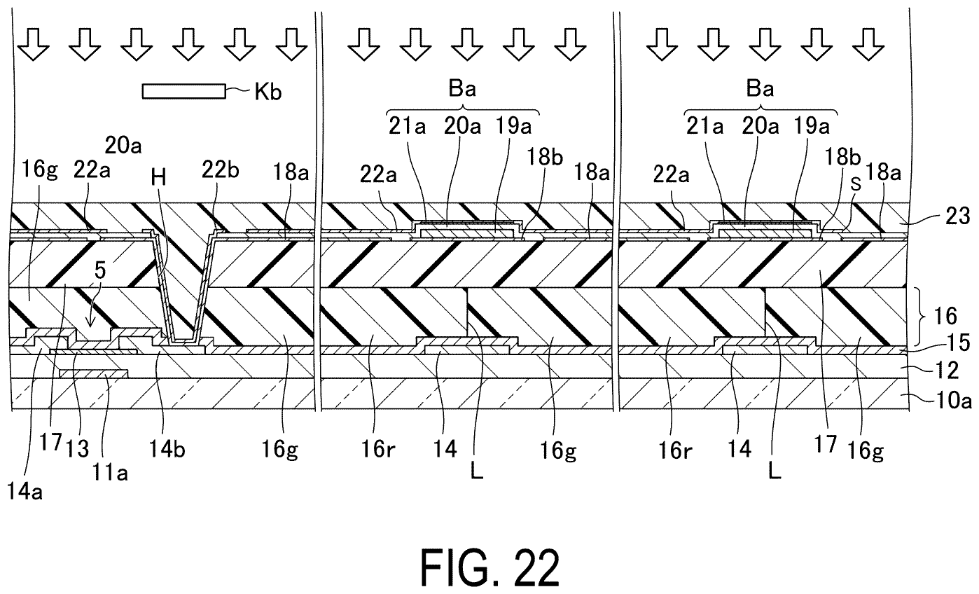

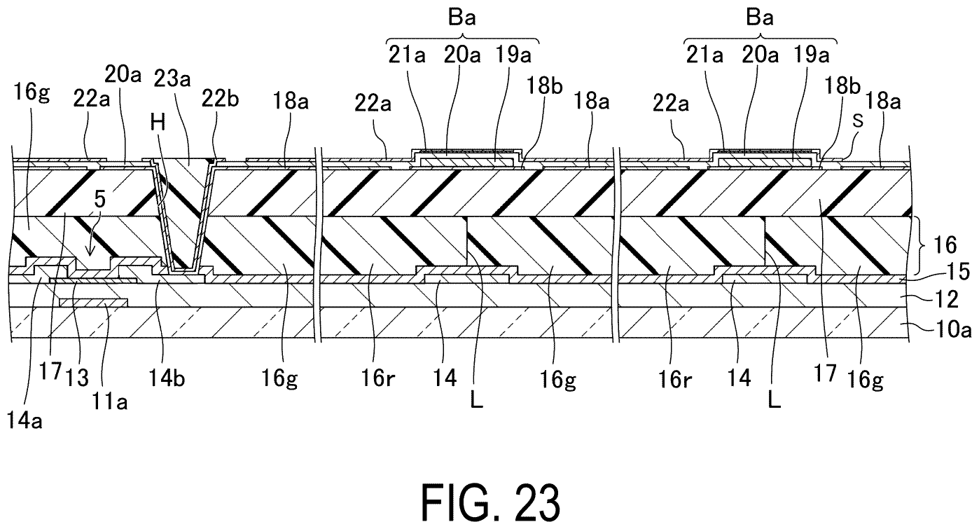

After that, as illustrated in FIG. 22, an acrylic photosensitive resin with a thickness of approximately 2.5 μm is applied by, for example, spin coating or slit coating to the surface of the substrate on which the common electrode 22a and the like are formed, and a coating film 23 that has been applied is partially exposed by using a graytone mask Kb and then developed and baked, thereby forming the resin layer 23a as illustrated in FIG. 23.

Further, an inorganic insulating film (with a thickness of approximately 30 nm) such as a silicon nitride film is formed by, for example, plasma CVD on the surface of the substrate on which the resin layer 23a is formed, thereby forming the inorganic protection film 24.

Finally, a polyimide resin film is applied by, for example, printing to the entire substrate on which the inorganic protection film 24 is formed, and then the resin film is subjected to baking and rubbing, thereby forming the alignment film 29.

As described above, the active matrix substrate 30a can be manufactured. Note that in the present embodiment, the method of manufacturing in which the first formation for anti-reflection layer is performed after the pixel electrode formation is exemplified, but as illustrated in FIGS. 24 to 27, a method of manufacturing in which the pixel electrode formation is performed after the first formation for anti-reflection layer may be employed.

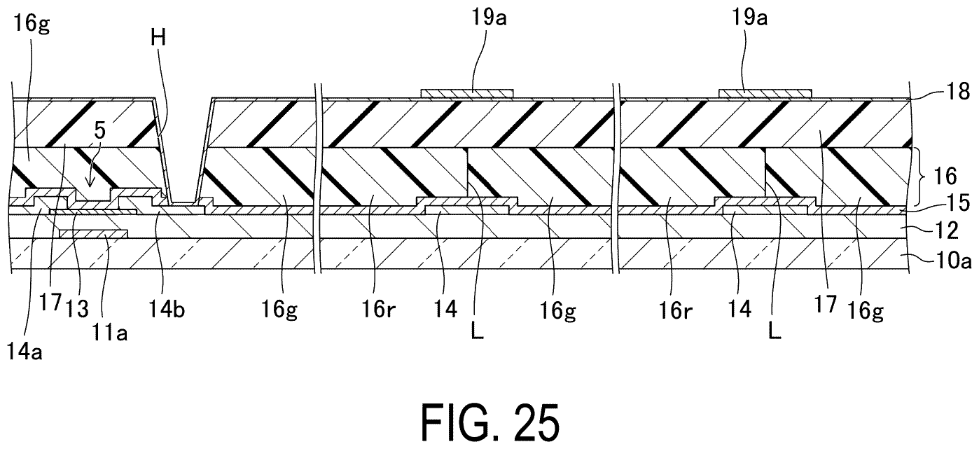

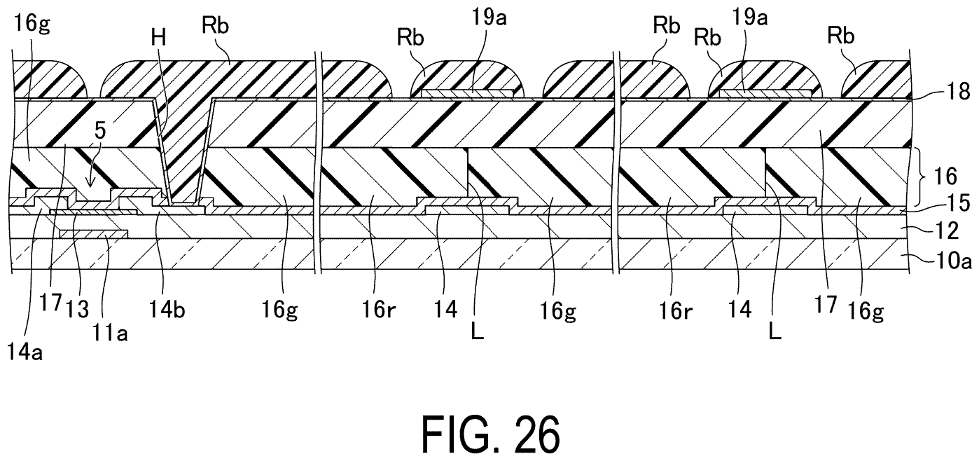

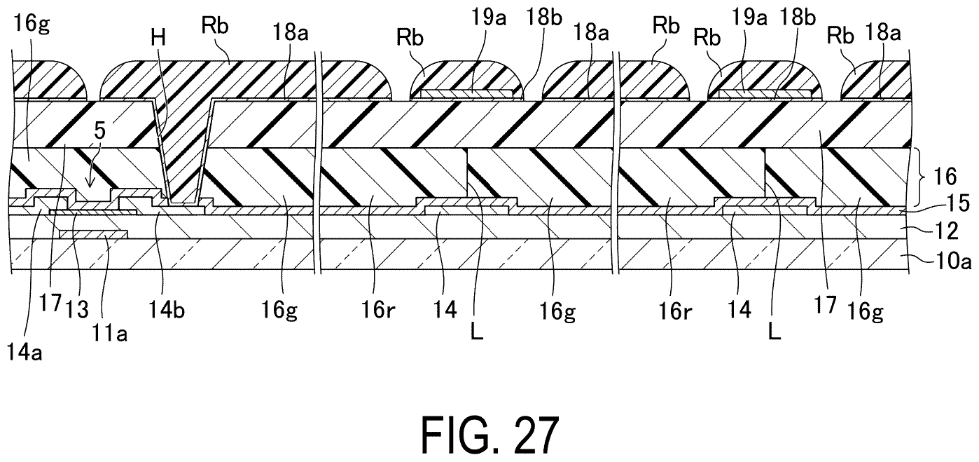

In detail, as illustrated in FIG. 24, the transparent conductive film 18 and the first metal film 19 are sequentially formed by, for example, sputtering on the surface of the substrate in which the contact hole H is formed in the interlayer insulating film 15 described above, and then, the first metal film 19 is subjected to photolithography, etching, and stripping and cleaning of the resist to form the first metal layer 19a as illustrated in FIG. 25 (first formation for anti-reflection layer). After that, the resist pattern Rb is formed as illustrated in FIG. 26, and the transparent conductive film 18 exposed from the resist pattern Rb is removed as illustrated in FIG. 27, thereby forming the pixel electrode 18a and the transparent conductive layer 18b (pixel electrode formation).

Further, the active matrix substrate 30a manufactured as described above and the counter substrate 40 are bonded with a sealing member having a frame-like shape, and a liquid crystal material is sealed between the active matrix substrate 30a and the counter substrate 40 to form the liquid crystal layer 45, thereby manufacturing the liquid crystal display device 50.

As described above, according to the active matrix substrate 30a, the liquid crystal display device 50 including the active matrix substrate 30a, and the method of manufacturing the active matrix substrate 30a of the present embodiment, first, in the first formation for anti-reflection layer, the first metal layer 19a having a belt shape is formed to be relatively thick and to overlap the boundary portion L between the colored layers (for example, the red layer 16r and the green layer 16g) of different colors from each other in the color filter 16. Subsequently, in the capacitance insulating film formation, the capacitance insulating film 20a is formed on the pixel electrodes 18a. Furthermore, in the second formation for anti-reflection layer, the second metal layer 21a having a belt shape is formed to be relatively thin and to overlap the boundary portion L between the colored layers (for example, the red layer 16r and the green layer 16g) of different colors from each other in the color filter 16. Accordingly, the anti-reflection layer Ba in which the first metal layer 19a that is relatively thick, the capacitance insulating film 20a, and the second metal layer 21a that is relatively thin are sequentially layered can be formed in a belt shape so as to overlap the boundary portion L between the colored layers (for example, the red layer 16r and the green layer 16g) of different colors from each other in the color filter 16. Thereafter, in the common electrode formation, the common electrode 23a is formed so as to cover the second metal layer 21a of the anti-reflection layer Ba. Here, in the formation of the anti-reflection layer Ba, the capacitance insulating film 20a constituting the anti-reflection layer Ba and the auxiliary capacity C is formed after the first metal layer 19a being relatively thick and constituting the anti-reflection layer Ba is formed, and thus, recess formation of the capacitance insulating film 20a can be suppressed in the formation of the anti-reflection layer Ba, and step formation of the capacitance insulating film 20a caused by the formation of the anti-reflection layer Ba can be suppressed. Further, since the capacitance insulating film 20a constituting the auxiliary capacity C also serves as an interlayer film between the first metal layer 19a and the second metal layer 21a constituting the anti-reflection layer Ba, the manufacturing cost of the active matrix substrate 30a can be reduced.

Additionally, according to the method of manufacturing the active matrix substrate 30a of the present embodiment, in the second formation for anti-reflection layer, the second metal film 21 and the resist film R being the positive type are formed in order so as to cover the capacitance insulating film 20a, and the resist film R is exposed from the base substrate 10a side through the first metal layer 19a. Then, the resist film R is exposed from a side opposite to the base substrate 10a through the photomask Ka to form the resist pattern Ra, and the second metal film 21 is patterned using the resist pattern Ra to form the second metal layer 21a. Accordingly, since the second metal layer 21a is formed in a self-aligned manner by using the first metal layer 19a, the first metal layer 19a and the second metal layer 21a can be exactly overlapped with each other, and a decrease in aperture ratio of the subpixel P due to misalignment can be suppressed.

### Second Embodiment

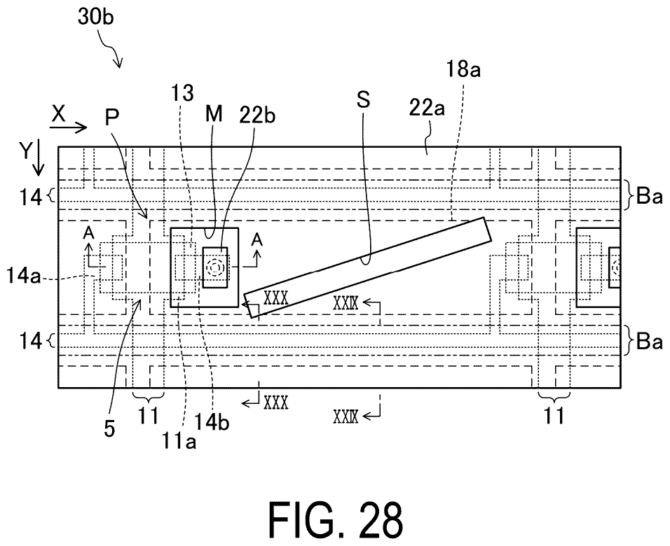

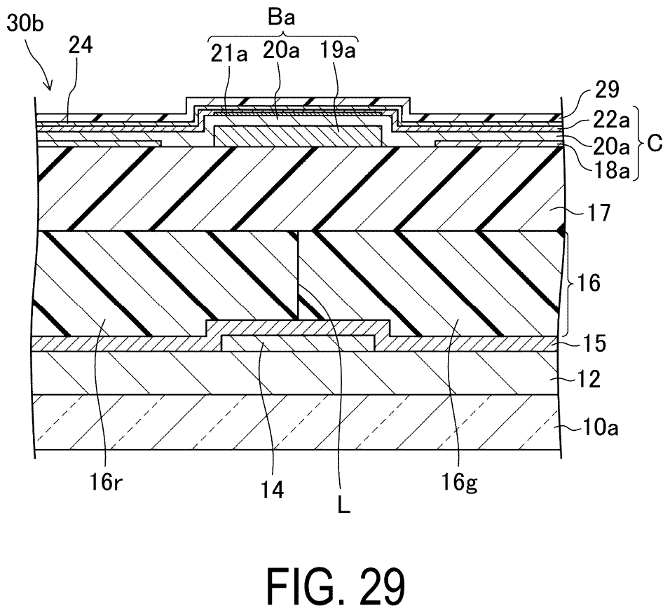

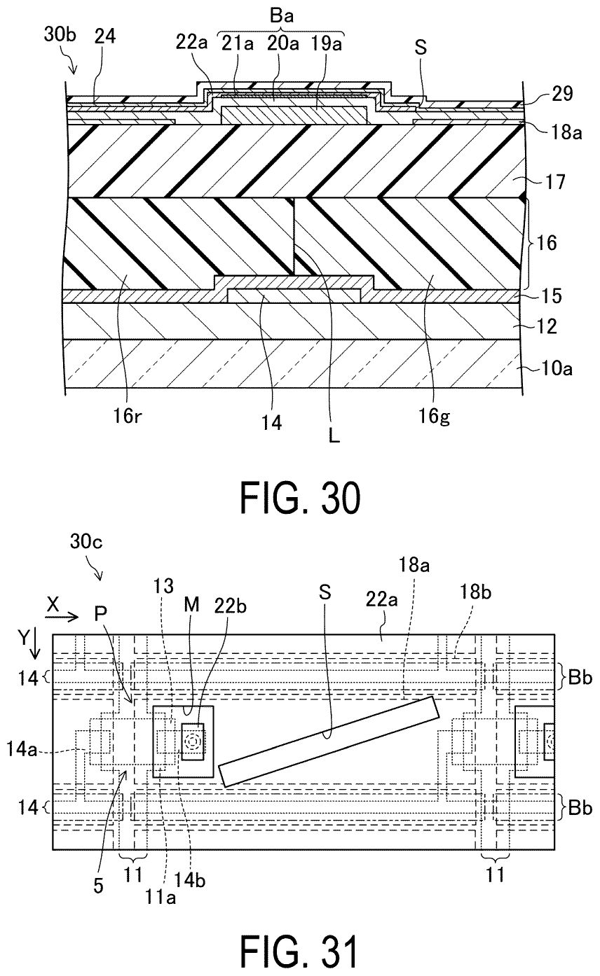

FIGS. 28 to 30 illustrate a second embodiment of an active matrix substrate, a liquid crystal display device including the active matrix substrate, and a method of manufacturing the active matrix substrate, according to the disclosure. Here, FIG. 28 is a plan view of an active matrix substrate 30b that is a component of the liquid crystal display device according to the present embodiment. Additionally, FIGS. 29 and 30 are cross-sectional views of the active matrix substrate 30b taken along a line XXIX-XXIX and a line XXX-XXX in FIG. 28, respectively. Note that a cross-sectional view of the active matrix substrate 30b taken along a line A-A in FIG. 28 is substantially the same as the portion of the active matrix substrate 30a in the cross-sectional view of FIG. 2. In addition, in the following embodiments, portions identical to those in FIGS. 1 to 27 will be denoted by the same reference signs, and detailed descriptions thereof will be omitted.

In the first embodiment described above, the liquid crystal display device 50 including the active matrix substrate 30a provided with the anti-reflection layer Ba on the organic protection film 17 through the transparent conductive layer 18b is exemplified. In the present embodiment, the liquid crystal display device including the active matrix substrate 30b provided with the anti-reflection layer Ba on the organic protection film 17 without the transparent conductive layer 18b is exemplified.

The liquid crystal display device according to the present embodiment includes the active matrix substrate 30b having a COA structure, the counter substrate 40 (see FIGS. 2 to 4) provided so as to face the active matrix substrate 30b, and the liquid crystal layer 45 (see FIGS. 2 to 4) provided between the active matrix substrate 30b and the counter substrate 40. In the liquid crystal display device according to the present embodiment, a plurality of subpixels P are provided in a matrix shape in a display region, as in the liquid crystal display device 50 according to the first embodiment. Note that in the display region, as in the liquid crystal display device 50 according to the first embodiment, the subpixels P disposed with the red layers 16r, the subpixels P disposed with the green layers 16g, and the subpixels P disposed with the blue layers are provided so as to be adjacent to one another.

As illustrated in FIGS. 29 and 30, the active matrix substrate 30b includes the base substrate 10a such as a glass substrate, a plurality of TFTs 5 provided on the base substrate 10a so as to correspond to a plurality of subpixels P, the color filter 16 provided on the plurality of TFTs 5, the organic protection film 17 provided on the color filter 16, a plurality of pixel electrodes 18a provided in a matrix shape on the organic protection film 17 so as to correspond to the plurality of subpixels P, the capacitance insulating film 20a provided on the plurality of pixel electrodes 18a, the common electrode 22a provided commonly to the plurality of subpixels P on the capacitance insulating film 20a, the inorganic protection film 24 provided on the common electrode 20a, and the alignment film 29 provided on the inorganic protection film 24. The active matrix substrate 30b includes a plurality of gate lines 11 and a plurality of source lines 14 as in the active matrix substrate 30a of the first embodiment. Note that in the active matrix substrate 30b, as illustrated in FIG. 28, the transparent conductive layer 18b (see FIG. 1) provided between a pair of pixel electrodes 18a adjacent to each other in an extending direction of the gate line 11 in the active matrix substrate 30a of the first embodiment is omitted.

As illustrated in FIGS. 28, 29, and 30, the anti-reflection layer Ba is provided in a belt shape over the entire display region so as to overlap the source line 14 and the boundary portion L between the colored layers (for example, the red layer 16r and the green layer 16g) of different colors from each other in the color filter 16. Additionally, as illustrated in FIGS. 29 and 30, the anti-reflection layer Ba includes the first metal layer 19a, the capacitance insulating film 20a, and the second metal layer 21a layered in order on the organic protection film 17, and is configured to suppress reflection of light incident from the liquid crystal layer 45 side by reflecting light incident from the liquid crystal layer 45 side at the second metal layer 21a, reflecting, at the first metal layer 19a, light transmitted through the second metal layer 21a without being reflected at the second metal layer 21a, and causing the light reflected at the second metal layer 21a and the light reflected at the first metal layer 19a to cancel each other.

In the liquid crystal display device including the active matrix substrate 30b having the above-described configuration, as in the liquid crystal display device 50 of the first embodiment described above, a predetermined voltage is applied to the auxiliary capacity C and the liquid crystal layer 45 disposed between each pixel electrode 18a and the common electrode 22a, and the alignment state of the liquid crystal layer 45 is changed by an electrical field generated in a horizontal direction, thereby adjusting the transmittance of light passing through the panel of each subpixel P to display an image.

The liquid crystal display device including the active matrix substrate 30b of the present embodiment can be manufactured by omitting the formation of the transparent conductive layer 18b in the pixel electrode formation of the method of manufacturing the active matrix substrate 30a of the first embodiment.

As described above, according to the active matrix substrate 30b, the liquid crystal display device including the active matrix substrate 30b, and the method of manufacturing the active matrix substrate 30b of the present embodiment, first, in the first formation for anti-reflection layer, the first metal layer 19a having a belt shape is formed to be relatively thick and to overlap the boundary portion L between the colored layers (for example, the red layer 16r and the green layer 16g) of different colors from each other in the color filter 16. Subsequently, in the capacitance insulating film formation, the capacitance insulating film 20a is formed on the pixel electrodes 18a. Furthermore, in the second formation for anti-reflection layer, the second metal layer 21a having a belt shape is formed to be relatively thin and to overlap the boundary portion L between the colored layers (for example, the red layer 16r and the green layer 16g) of different colors from each other in the color filter 16. Accordingly, the anti-reflection layer Ba in which the first metal layer 19a that is relatively thick, the capacitance insulating film 20a, and the second metal layer 21a that is relatively thin are sequentially layered can be formed in a belt shape so as to overlap the boundary portion L between the colored layers (for example, the red layer 16r and the green layer 16g) of different colors from each other in the color filter 16. Thereafter, in the common electrode formation, the common electrode 23a is formed so as to cover the second metal layer 21a of the anti-reflection layer Ba. Here, in the formation of the anti-reflection layer Ba, the capacitance insulating film 20a constituting the anti-reflection layer Ba and the auxiliary capacity C is formed after the first metal layer 19a being relatively thick and constituting the anti-reflection layer Ba is formed, and thus, recess formation of the capacitance insulating film 20a can be suppressed in the formation of the anti-reflection layer Ba, and step formation of the capacitance insulating film 20a caused by the formation of the anti-reflection layer Ba can be suppressed. Further, since the capacitance insulating film 20a constituting the auxiliary capacity C also serves as an interlayer film between the first metal layer 19a and the second metal layer 21a constituting the anti-reflection layer Ba, the manufacturing cost of the active matrix substrate 30b can be reduced.

Additionally, according to the method of manufacturing the active matrix substrate 30b of the present embodiment, in the second formation for anti-reflection layer, the second metal film 21 and the resist film R being the positive type are formed in order so as to cover the capacitance insulating film 20a, the resist film R is exposed from the base substrate 10a side through the first metal layer 19a, then, the resist film R is exposed from the side opposite to the base substrate 10a through the photomask Ka to form the resist pattern Ra, and the second metal film 21 is patterned by using the resist pattern Ra to form the second metal layer 21a. Accordingly, since the second metal layer 21a is formed in a self-aligned manner by using the first metal layer 19a, the first metal layer 19a and the second metal layer 21a can be exactly overlapped with each other, and a decrease in aperture ratio of the subpixel P due to misalignment can be suppressed.

### Third Embodiment

FIG. 31 illustrates a third embodiment of an active matrix substrate, a liquid crystal display device including the active matrix substrate, and a method of manufacturing the active matrix substrate, according to the disclosure. Here, FIG. 31 is a plan view of an active matrix substrate 30c that is a component of the liquid crystal display device according to the present embodiment.

In the first embodiment, the liquid crystal display device 50 including the active matrix substrate 30a provided with the anti-reflection layer Ba having a belt shape and being relatively long is exemplified. In the present embodiment, the liquid crystal display device including the active matrix substrate 30c provided with an anti-reflection layer Bb having a belt shape and being relatively short is exemplified.

The liquid crystal display device according to the present embodiment includes the active matrix substrate 30c having a COA structure, the counter substrate 40 (see FIGS. 2 to 4) provided so as to face the active matrix substrate 30c, and the liquid crystal layer 45 (see FIGS. 2 to 4) provided between the active matrix substrate 30c and the counter substrate 40. In the liquid crystal display device according to the present embodiment, a plurality of subpixels P are provided in a matrix shape in a display region, as in the liquid crystal display device 50 according to the first embodiment. Note that in the display region, as in the liquid crystal display device 50 according to the first embodiment, the subpixels P disposed with the red layers 16r, the subpixels P disposed with the green layers 16g, and the subpixels P disposed with the blue layers are provided so as to be adjacent to one another.

As in the active matrix substrate 30a of the first embodiment described above, the active matrix substrate 30c includes the base substrate 10a, a plurality of TFTs 5 provided on the base substrate 10a so as to correspond to the plurality of subpixels P, the color filter 16 provided on the plurality of TFTs 5, the organic protection film 17 provided on the color filter 16, a plurality of pixel electrodes 18a provided on the organic protection film 17 in a matrix shape so as to correspond to the plurality of subpixels P, the capacitance insulating film 20a provided on the plurality of pixel electrodes 18a, the common electrode 22a provided commonly to the plurality of subpixels P on the capacitance insulating film 20a, the inorganic protection film 24 provided on the common electrode 20a, and the alignment film 29 provided on the inorganic protection film 24. Further, the active matrix substrate 30c includes a plurality of gate lines 11 and a plurality of source lines 14 as in the active matrix substrate 30a of the first embodiment described above. In addition, in the active matrix substrate 30c, as illustrated in FIG. 31, the transparent conductive layer 18b is provided between a pair of pixel electrodes 18a adjacent to each other in an extending direction of the gate line 11 (Y direction in the drawing), and the anti-reflection layer Bb is provided on the transparent conductive layer 18b.

As illustrated in FIG. 31, the anti-reflection layer Bb is provided in a belt shape so as to overlap the source line 14 and the boundary portion L between the colored layers of different colors from each other (for example, the red layer 16r and the green layer 16g) in the color filter 16, and is divided for each subpixel P. Additionally, same as the anti-reflection layer Ba of the first embodiment described above, the anti-reflection layer Bb includes the first metal layer 19a, the capacitance insulating film 20a, and the second metal layer 21a layered in order on the transparent conductive layer 18b, and is configured to suppress reflection of light incident from the liquid crystal layer 45 side by reflecting light incident from the liquid crystal layer 45 side at the second metal layer 21a, reflecting, at the first metal layer 19a, light transmitted through the second metal layer 21a without being reflected at the second metal layer 21a, and causing the light reflected at the second metal layer 21a and the light reflected at the first metal layer 19a to cancel each other.

In the liquid crystal display device including the active matrix substrate 30c having the configuration described above, as in the liquid crystal display device 50 of the first embodiment, a predetermined voltage is applied to the auxiliary capacity C and the liquid crystal layer 45 disposed between each pixel electrode 18a and the common electrode 22a, and the alignment state of the liquid crystal layer 45 is changed by an electrical field generated in a horizontal direction, thereby adjusting the transmittance of light passing through the panel of each subpixel P to display an image.

The liquid crystal display device including the active matrix substrate 30c of the present embodiment can be manufactured by changing a pattern shape of each of the first metal layer 19a and the second metal layer 21a to be discontinuous in the first formation for anti-reflection layer and the second formation for anti-reflection layer in the method of manufacturing the active matrix substrate 30a of the first embodiment.

As described above, according to the active matrix substrate 30c, the liquid crystal display device including the active matrix substrate 30c, and the method of manufacturing the active matrix substrate 30c of the present embodiment, first, in the first formation for anti-reflection layer, the first metal layer 19a having a belt shape is formed to be relatively thick and to overlap the boundary portion L between the colored layers (for example, the red layer 16r and the green layer 16g) of different colors from each other in the color filter 16. Subsequently, in the capacitance insulating film formation, the capacitance insulating film 20a is formed on the pixel electrodes 18a. Furthermore, in the second formation for anti-reflection layer, the second metal layer 21a having a belt shape is formed to be relatively thin and to overlap the boundary portion L between the colored layers (for example, the red layer 16r and the green layer 16g) of different colors from each other in the color filter 16. Thus, the anti-reflection layer Bb in which the first metal layer 19a being relatively thick, the capacitance insulating film 20a, and the second metal layer 21a being relatively thin are sequentially layered can be formed in a belt shape so as to overlap the boundary portion L between the colored layers (for example, the red layer 16r and the green layer 16g) of different colors from each other in the color filter 16. Thereafter, in the common electrode formation, the common electrode 23a is formed so as to cover the second metal layer 21a of the anti-reflection layer Bb. Here, in the formation of the anti-reflection layer Bb, the first metal layer 19a being relatively thick and constituting the anti-reflection layer Bb is formed, and then, the capacitance insulating film 20a constituting the anti-reflection layer Bb and the auxiliary capacity C is formed. Thus, when the anti-reflection layer Bb is formed, recess formation of the capacitance insulating film 20a is suppressed, and step formation of the capacitance insulating film 20a due to the formation of the anti-reflection layer Bb can be suppressed. Further, since the capacitance insulating film 20a constituting the auxiliary capacity C also serves as an interlayer film between the first metal layer 19a and the second metal layer 21a constituting the anti-reflection layer Bb, the manufacturing cost of the active matrix substrate 30c can be reduced.

Additionally, according to the method of manufacturing the active matrix substrate 30c of the present embodiment, in the second formation for anti-reflection layer, the second metal film 21 and the resist film R being the positive type are formed in order so as to cover the capacitance insulating film 20a, the resist film R is exposed from the base substrate 10a side through the first metal layer 19a, the resist film R is exposed from the side opposite to the base substrate 10a through the photomask Ka to form the resist pattern Ra, and the second metal film 21 is patterned by using the resist pattern Ra to form the second metal layer 21a. Accordingly, since the second metal layer 21a is formed in a self-aligned manner by using the first metal layer 19a, the first metal layer 19a and the second metal layer 21a can be exactly overlapped with each other, and a decrease in aperture ratio of the subpixel P due to misalignment can be suppressed.

In addition, according to the active matrix substrate 30c of the present embodiment, division of the anti-reflection layer Bb for each subpixel P can suppress, for example, a short circuit between the pixel electrodes 18a adjacent to each other in the extending direction of the source line 14 through the first metal layer 19a of the anti-reflection layer Bb due to patterning failure or the like.

### Fourth Embodiment

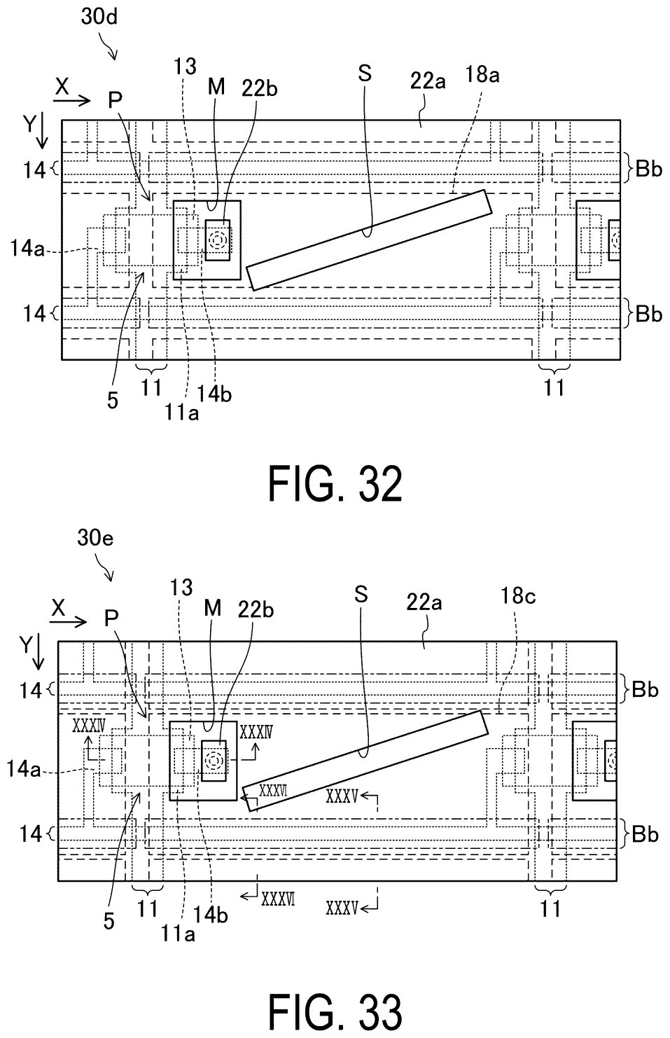

FIG. 32 illustrates a fourth embodiment of an active matrix substrate, a liquid crystal display device including the active matrix substrate, and a method of manufacturing the active matrix substrate, according to the disclosure. Here, FIG. 32 is a plan view of an active matrix substrate 30d that is a component of the liquid crystal display device according to the present embodiment.

In the first embodiment described above, the liquid crystal display device 50 including the active matrix substrate 30a provided with the anti-reflection layer Ba having a belt shape and being relatively long through the transparent conductive layer 18b on the organic protection film 17 is exemplified. In the present embodiment, the liquid crystal display device including the active matrix substrate 30d provided with the anti-reflection layer Ba having a belt shape and being relatively short on the organic protection film 17 without the transparent conductive layer 18b is exemplified.

The liquid crystal display device according to the present embodiment includes the active matrix substrate 30d having a COA structure, the counter substrate 40 (see FIGS. 2 to 4) provided so as to face the active matrix substrate 30d, and the liquid crystal layer 45 (see FIGS. 2 to 4) provided between the active matrix substrate 30d and the counter substrate 40. In the liquid crystal display device according to the present embodiment, a plurality of subpixels P are provided in a matrix shape in a display region, as in the liquid crystal display device 50 according to the first embodiment. Note that in the display region, as in the liquid crystal display device 50 according to the first embodiment, the subpixels P disposed with the red layers 16r, the subpixels P disposed with the green layers 16g, and the subpixels P disposed with the blue layers are provided so as to be adjacent to one another.

As in the active matrix substrate 30a of the first embodiment described above, the active matrix substrate 30d includes the base substrate 10a, a plurality of TFTs 5 provided on the base substrate 10a so as to correspond to the plurality of subpixels P, the color filter 16 provided on the plurality of TFTs 5, the organic protection film 17 provided on the color filter 16, a plurality of pixel electrodes 18a provided on the organic protection film 17 in a matrix shape so as to correspond to the plurality of subpixels P, the capacitance insulating film 20a provided on the plurality of pixel electrodes 18a, the common electrode 22a provided commonly to the plurality of subpixels P on the capacitance insulating film 20a, the inorganic protection film 24 provided on the common electrode 20a, and the alignment film 29 provided on the inorganic protection film 24. Further, the active matrix substrate 30d includes a plurality of gate lines 11 and a plurality of source lines 14 as in the active matrix substrate 30a of the first embodiment. Note that as illustrated in FIG. 32, in the active matrix substrate 30d, the transparent conductive layer 18b (see FIG. 1) provided between a pair of pixel electrodes 18a adjacent to each other in the extending direction of the gate line 11 in the active matrix substrate 30a of the first embodiment is omitted, as in the active matrix substrate 30b of the second embodiment.

As illustrated in FIG. 32, the anti-reflection layer Bb is provided in a belt shape so as to overlap the source line 14 and the boundary portion L between the colored layers of different colors from each other (for example, the red layer 16r and the green layer 16g) in the color filter 16, and is divided for each subpixel P. Additionally, as in the anti-reflection layer Ba of the second embodiment, the anti-reflection layer Bb includes the first metal layer 19a, the capacitance insulating film 20a, and the second metal layer 21a layered in order on the organic protection film 17, and is configured to suppress reflection of light incident from the liquid crystal layer 45 side by reflecting light incident from the liquid crystal layer 45 side at the second metal layer 21a, reflecting, at the first metal layer 19a, light transmitted through the second metal layer 21a without being reflected at the second metal layer 21a, and causing the light reflected at the second metal layer 21a and the light reflected at the first metal layer 19a to cancel each other.

In the liquid crystal display device including the active matrix substrate 30d having the configuration described above, as in the liquid crystal display device 50 of the first embodiment, a predetermined voltage is applied to the auxiliary capacity C and the liquid crystal layer 45 disposed between each pixel electrode 18a and the common electrode 22a, and the alignment state of the liquid crystal layer 45 is changed by an electrical field generated in a horizontal direction, thereby adjusting the transmittance of light passing through the panel of each subpixel P to display an image.

The liquid crystal display device including the active matrix substrate 30d of the present embodiment can be manufactured by omitting the formation of the transparent conductive layer 18b in the pixel electrode formation in the method of manufacturing the active matrix substrate 30a of the first embodiment, and changing a pattern shape of each of the first metal layer 19a and the second metal layer 21a to be discontinuous in the first formation for anti-reflection layer and the second formation for anti-reflection layer.

As described above, according to the active matrix substrate 30d, the liquid crystal display device including the active matrix substrate 30d, and the method of manufacturing the active matrix substrate 30d of the present embodiment, first, in the first formation for anti-reflection layer, the first metal layer 19a having a belt shape is formed to be relatively thick and to overlap the boundary portion L between the colored layers (for example, the red layer 16r and the green layer 16g) of different colors from each other in the color filter 16. Subsequently, in the capacitance insulating film formation, the capacitance insulating film 20a is formed on the pixel electrodes 18a. Furthermore, in the second formation for anti-reflection layer, the second metal layer 21a having a belt shape is formed to be relatively thin and to overlap the boundary portion L between the colored layers (for example, the red layer 16r and the green layer 16g) of different colors from each other in the color filter 16. Thus, the anti-reflection layer Bb in which the first metal layer 19a being relatively thick, the capacitance insulating film 20a, and the second metal layer 21a being relatively thin are sequentially layered can be formed in a belt shape so as to overlap the boundary portion L between the colored layers (for example, the red layer 16r and the green layer 16g) of different colors from each other in the color filter 16. Thereafter, in the common electrode formation, the common electrode 23a is formed so as to cover the second metal layer 21a of the anti-reflection layer Bb. Here, in the formation of the anti-reflection layer Bb, the first metal layer 19a being relatively thick and constituting the anti-reflection layer Bb is formed, and then, the capacitance insulating film 20a constituting the anti-reflection layer Bb and the auxiliary capacity C is formed. Thus, when the anti-reflection layer Bb is formed, recess formation of the capacitance insulating film 20a is suppressed, and step formation of the capacitance insulating film 20a due to the formation of the anti-reflection layer Bb can be suppressed. Further, since the capacitance insulating film 20a constituting the auxiliary capacity C also serves as an interlayer film between the first metal layer 19a and the second metal layer 21a constituting the anti-reflection layer Bb, the manufacturing cost of the active matrix substrate 30d can be reduced.

Further, according to the method of manufacturing the active matrix substrate 30d of the present embodiment, in the second formation of the anti-reflection layer, the second metal film 21 and the resist film R being the positive type are formed in order so as to cover the capacitance insulating film 20a, the resist film R is exposed from the base substrate 10a side through the first metal layer 19a, then, the resist film R is exposed from the side opposite to the base substrate 10a through the photomask Ka to form the resist pattern Ra, and the second metal film 21 is patterned by using the resist pattern Ra to form the second metal layer 21a. Accordingly, since the second metal layer 21a is formed in a self-aligned manner by using the first metal layer 19a, the first metal layer 19a and the second metal layer 21a can be exactly overlapped with each other, and a decrease in aperture ratio of the subpixel P due to misalignment can be suppressed.

In addition, according to the active matrix substrate 30d of the present embodiment, division of the anti-reflection layer Bb for each subpixel P can suppress, for example, a short circuit between the pixel electrodes 18a adjacent to each other in the extending direction of the source line 14 through the first metal layer 19a of the anti-reflection layer Bb due to patterning failure or the like.

### Fifth Embodiment

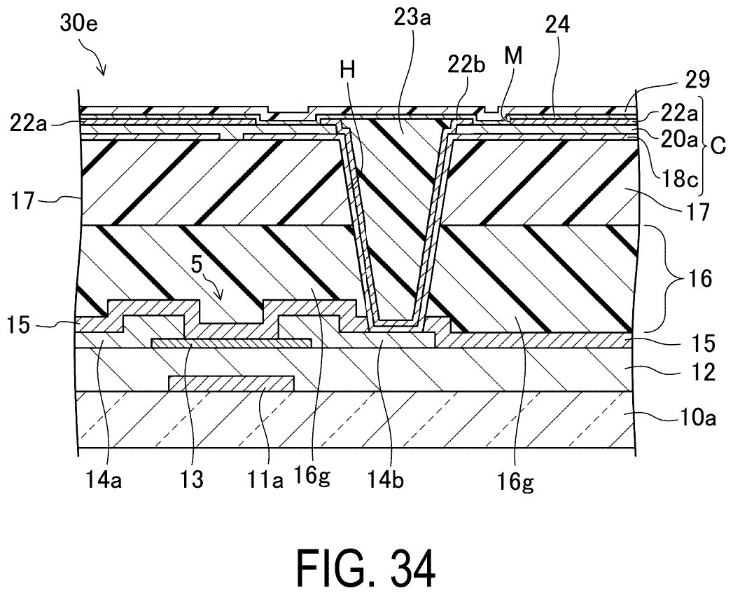

FIGS. 33 to 36 illustrate a fifth embodiment of an active matrix substrate, a liquid crystal display device including the active matrix substrate, and a method of manufacturing the active matrix substrate, according to the disclosure. Here, FIG. 33 is a plan view of an active matrix substrate 30e that is a component of the liquid crystal display device according to the present embodiment. Additionally, FIGS. 34, 35, and 36 are cross-sectional views of the active matrix substrate 30e taken along a line XXXIV-XXXIV, a line XXXV-XXXV, and a line XXXVI-XXXVI in FIG. 33, respectively.

In the first embodiment, the liquid crystal display device 50 including the active matrix substrate 30a in which the pixel electrodes 18a do not cover the source lines 14 and the anti-reflection layer Ba has belt shapes and is relatively long is exemplified. In the present embodiment, the liquid crystal display device including the active matrix substrate 30e in which pixel electrodes 18c cover the source lines 14 and the anti-reflection layer Bb has belt shapes and is relatively short is exemplified.

The liquid crystal display device according to the present embodiment includes the active matrix substrate 30e having a COA structure, the counter substrate 40 (see FIGS. 2 to 4) provided so as to face the active matrix substrate 30e, and the liquid crystal layer 45 (see FIGS. 2 to 4) provided between the active matrix substrate 30e and the counter substrate 40. In the liquid crystal display device according to the present embodiment, a plurality of subpixels P are provided in a matrix shape in a display region, as in the liquid crystal display device 50 according to the first embodiment. Note that in the display region, as in the liquid crystal display device 50 according to the first embodiment, the subpixels P disposed with the red layers 16r, the subpixels P disposed with the green layers 16g, and the subpixels P disposed with the blue layers are provided so as to be adjacent to one another.

As illustrated in FIGS. 34 to 36, the active matrix substrate 30e includes the base substrate 10a, a plurality of TFTs 5 provided on the base substrate 10a so as to correspond to the plurality of subpixels P, the color filter 16 provided on the plurality of TFTs 5, the organic protection film 17 provided on the color filter 16, a plurality of pixel electrodes 18c provided on the organic protection film 17 in a matrix shape so as to correspond to the plurality of subpixels P, the capacitance insulating film 20a provided on the plurality of pixel electrodes 18c, the common electrode 22a provided commonly to the plurality of subpixels P on the capacitance insulating film 20a, the inorganic protection film 24 provided on the common electrode 20a, and the alignment film 29 provided on the inorganic protection film 24. Additionally, the active matrix substrate 30e includes a plurality of gate lines 11 and a plurality of source lines 14 as in the active matrix substrate 30a of the first embodiment described above.

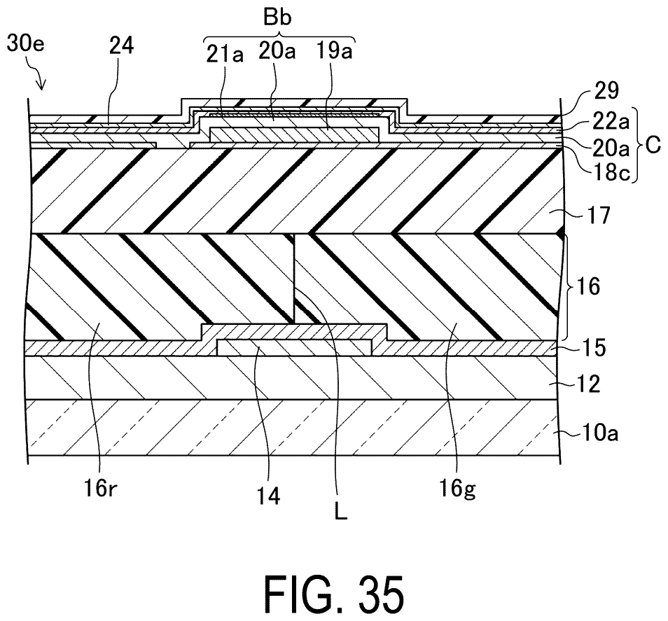

As illustrated in FIGS. 33 to 36, the pixel electrode 18c is provided in a rectangular shape on the organic protection film 17. Further, as illustrated in FIG. 33, the pixel electrode 18c is provided so as to overlap the corresponding anti-reflection layer Bb on the positive side in the Y direction in the drawing (so as to extend further than the pixel electrode 18a in the first embodiment). Here, as illustrated in FIG. 34 and FIG. 35, the pixel electrode 18c constitutes the auxiliary capacity C of each subpixel P together with the common electrode 22a and the capacitance insulating film 20a provided between the pixel electrode 18c and the common electrode 22a.

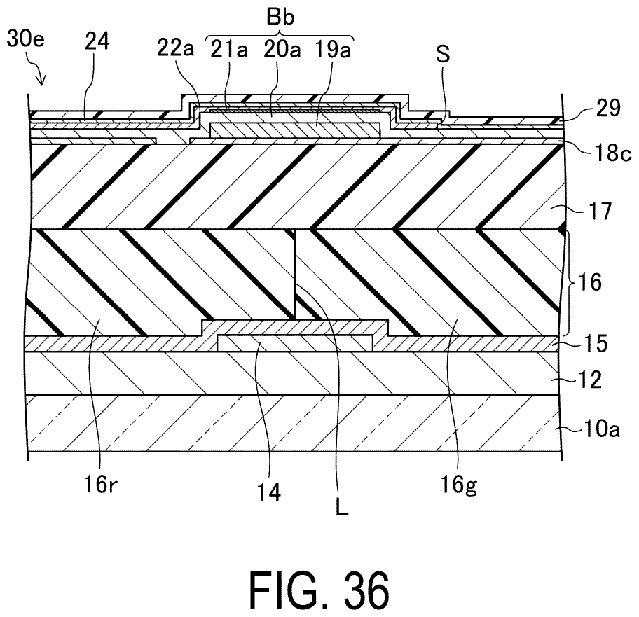

As illustrated in FIGS. 33, 35, and 36, the anti-reflection layer Bb is provided in a belt shape so as to overlap the source line 14 and the boundary portion L between the colored layers (for example, the red layer 16r and the green layer 16g) of different colors from each other in the color filter 16, and is divided for each subpixel P. Additionally, as illustrated in FIGS. 35 and 36, the anti-reflection layer Bb includes the first metal layer 19a, the capacitance insulating film 20a, and the second metal layer 21a layered in order on the pixel electrode 18c, and is configured to suppress reflection of light incident from the liquid crystal layer 45 side by reflecting light incident from the liquid crystal layer 45 side at the second metal layer 21a, reflecting, at the first metal layer 19a, light transmitted through the second metal layer 21a without being reflected at the second metal layer 21a, and causing the light reflected at the second metal layer 21a and the light reflected at the first metal layer 19a to cancel each other.

In the liquid crystal display device including the active matrix substrate 30e having the configuration described above, as in the liquid crystal display device 50 of the first embodiment, a predetermined voltage is applied to the auxiliary capacity C and the liquid crystal layer 45 disposed between each pixel electrode 18c and the common electrode 22a, and the alignment state of the liquid crystal layer 45 is changed by an electrical field generated in the horizontal direction, thereby adjusting the transmittance of light passing through the panel of each subpixel P to display an image.

The liquid crystal display device including the active matrix substrate 30e of the present embodiment can be manufactured by omitting the formation of the transparent conductive layer 18b and changing the pattern shape of the pixel electrode 18a in the pixel electrode formation in the method of manufacturing the active matrix substrate 30a of the first embodiment, and changing a pattern shape of each of the first metal layer 19a and the second metal layer 21a to be discontinuous in the first formation for anti-reflection layer and the second formation for anti-reflection layer.

As described above, according to the active matrix substrate 30e, the liquid crystal display device including the active matrix substrate 30e, and the method of manufacturing the active matrix substrate 30e of the present embodiment, first, in the first formation for anti-reflection layer, the first metal layer 19a having a belt shape is formed to be relatively thick and to overlap the boundary portion L between the colored layers (for example, the red layer 16r and the green layer 16g) of different colors from each other in the color filter 16. Subsequently, in the capacitance insulating film formation, the capacitance insulating film 20a is formed on the pixel electrodes 18c. Furthermore, in the second formation for anti-reflection layer, the second metal layer 21a having a belt shape is formed to be relatively thin and to overlap the boundary portion L between the colored layers (for example, the red layer 16r and the green layer 16g) of different colors from each other in the color filter 16. Thus, the anti-reflection layer Bb in which the first metal layer 19a being relatively thick, the capacitance insulating film 20a, and the second metal layer 21a being relatively thin are sequentially layered can be formed in a belt shape so as to overlap the boundary portion L between the colored layers (for example, the red layer 16r and the green layer 16g) of different colors from each other in the color filter 16. Thereafter, in the common electrode formation, the common electrode 23a is formed so as to cover the second metal layer 21a of the anti-reflection layer Bb. Here, in the formation of the anti-reflection layer Bb, the first metal layer 19a being relatively thick and constituting the anti-reflection layer Bb is formed, and then, the capacitance insulating film 20a constituting the anti-reflection layer Bb and the auxiliary capacity C is formed. Thus, when the anti-reflection layer Bb is formed, recess formation of the capacitance insulating film 20a is suppressed, and step formation of the capacitance insulating film 20a due to the formation of the anti-reflection layer Bb can be suppressed. Further, the capacitance insulating film 20a constituting the auxiliary capacity C also serves as an interlayer film between the first metal layer 19a and the second metal layer 21a constituting the anti-reflection layer Bb, causing the manufacturing cost of the active matrix substrate 30e to be reduced.

Additionally, according to the method of manufacturing the active matrix substrate 30e of the present embodiment, in the second formation for anti-reflection layer, the second metal film 21 and the resist film R being the positive type are formed in order so as to cover the capacitance insulating film 20a, the resist film R is exposed from the base substrate 10a side through the first metal layer 19a, then, the resist film R is exposed from the side opposite to the base substrate 10a through the photomask Ka to form the resist pattern Ra, and the second metal film 21 is patterned by using the resist pattern Ra to form the second metal layer 21a. Accordingly, since the second metal layer 21a is formed in a self-aligned manner by using the first metal layer 19a, the first metal layer 19a and the second metal layer 21a can be exactly overlapped with each other, and a decrease in aperture ratio of the subpixel P due to misalignment can be suppressed.

In addition, according to the active matrix substrate 30e of the present embodiment, division of the anti-reflection layer Bb for each subpixel P makes it possible to secure electrical insulation between the pixel electrodes 18c adjacent to each other in the extending direction of the source line 14.

### Other Embodiments

Although the active matrix substrates 30a, 30b, 30c, 30d, and 30e and the liquid crystal display devices including the active matrix substrates are exemplified in the above embodiments, the disclosure can also be applied to an active matrix substrate in which the configurations of the active matrix substrates 30a, 30b, 30c, 30d, and 30e are appropriately combined and a liquid crystal display device including the active matrix substrate.

Additionally, in each of the embodiments described above, the liquid crystal display device including the active matrix substrate in which the electrodes of the TFTs connected to the pixel electrodes serve as drain electrodes is exemplified. However, the disclosure is also applicable to a liquid crystal display device including an active matrix substrate in which the electrodes of the TFTs connected to the pixel electrodes serve as source electrodes.

### INDUSTRIAL APPLICABILITY

As described above, the disclosure is useful for the liquid crystal display device of the in-plane switching mode including the active matrix substrate having a color filter-on-array structure.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate comprising:
a base substrate;
a plurality of thin film transistors provided on the base substrate, the plurality of thin film transistors corresponding to a plurality of subpixels;
a color filter provided on the plurality of thin film transistors, the color filter being disposed with colored layers of predetermined colors corresponding to the plurality of subpixels;
a plurality of pixel electrodes provided on an upper side of the color filter, the plurality of pixel electrodes corresponding to the plurality of subpixels;
a capacitance insulating film provided on the plurality of pixel electrodes;
a common electrode provided commonly to the plurality of subpixels on the capacitance insulating film; and
an anti-reflection layer having belt shapes, each belt shape of the anti-reflection layer overlapping a boundary portion between the colored layers having different colors from each other in the color filter, the anti-reflection layer being formed by layering a first metal layer, the capacitance insulating film, and a second metal layer in order,
wherein the common electrode covers the second metal layer.

2. The active matrix substrate according to claim 1,
wherein a transparent conductive layer is provided in belt shapes in a layer identical to a layer of the plurality of pixel electrodes by using a material identical to a material of the plurality of pixel electrodes, each belt shape of the transparent conductive layer overlapping the boundary portion of the colored layers, and
the first metal layer is provided on the transparent conductive layer.

3. The active matrix substrate according to claim 1,
wherein the plurality of pixel electrodes overlap the corresponding belt shapes of the anti-reflection layer, and
the first metal layer is provided on the plurality of pixel electrodes.

4. The active matrix substrate according to claim 1,
wherein the anti-reflection layer is divided for each of the plurality of subpixels.

5. The active matrix substrate according to claim 1,
wherein the common electrode is provided with a slit for each of the plurality of subpixels.

6. The active matrix substrate according to claim 1,
wherein, at each of the plurality of subpixels, the corresponding pixel electrode among the plurality of pixel electrodes, the capacitance insulating film, and the common electrode constitute an auxiliary capacity.

7. A liquid crystal display device comprising:
the active matrix substrate according to claim 1;
a counter substrate facing the active matrix substrate; and
a liquid crystal layer provided between the active matrix substrate and the counter substrate.

8. A method of manufacturing an active matrix substrate comprising:
forming a plurality of thin film transistors corresponding to a plurality of subpixels on a base substrate as thin film transistor formation;
forming a color filter disposed with colored layers of predetermined colors corresponding to the plurality of subpixels on the plurality of thin film transistors as color filter formation;
forming a plurality of pixel electrodes corresponding to the plurality of subpixels on an upper side of the color filter as pixel electrode formation;
forming a first metal layer having belt shapes, each belt shape of the first metal layer overlapping a boundary portion between the colored layers having different colors from each other in the color filter as first formation for anti-reflection layer;
forming a capacitance insulating film on the plurality of pixel electrodes as capacitance insulating film formation;
forming a second metal layer having belt shapes, each belt shape of the second metal layer overlapping the boundary portion of the colored layers as second formation for anti-reflection layer; and
forming a common electrode covering the second metal layer as common electrode formation.

9. The method of manufacturing the active matrix substrate according to claim 8,
wherein in the pixel electrode formation, a transparent conductive film is formed on the upper side of the color filter, and then the transparent conductive film is patterned and thus the plurality of pixel electrodes are formed, and
in the first formation for anti-reflection layer, a first metal film is formed and thus covers the plurality of pixel electrodes, and then the first metal film is patterned and thus the first metal layer is formed.

10. The method of manufacturing the active matrix substrate according to claim 8, further comprising:
forming a transparent conductive film and a first metal film in order on the upper side of the color filter after the color filter formation;
wherein, in the first formation for anti-reflection layer, the first metal film is patterned and thus the first metal layer is formed, and then, in the pixel electrode formation, the transparent conductive film is patterned and thus the plurality of pixel electrodes are formed.

11. The method of manufacturing the active matrix substrate according to claim 8,
wherein in the second formation for anti-reflection layer,
a second metal film and a resist film being a positive type are formed in order and thus cover the capacitance insulating film,
the resist film is exposed from a side of the base substrate through the first metal layer, and then, the resist film is exposed from a side opposite to the base substrate through a mask and thus a resist pattern is formed, and
the second metal film is patterned by using the resist pattern and thus, the second metal layer is formed.
